(19) United States
(12) Patent Application Publication
(10) Pub. No.: US 2015/0327099 A1
(43) Pub. Date: Nov. 12, 2015

(54) Opportunistic Power Detection and Antenna Tuner Measurement During Concurrency

(71) Applicant: QUALCOMM Incorporated, San Diego, CA (US)

(72) Inventors: Francis Ming-Meng Ngai, Louisville, CO (US); Sai Kwok, Escondido, CA (US); Brian Michael George, San Diego, CA (US); Vamsee Krishna Babu Boda, San Diego, CA (US); Narendra Varma Gottimukkala, San Diego, CA (US); Erdogan Debe, San Diego, CA (US)

(73) Assignee: QUALCOMM Incorporated, San Diego, CA (US)

(21) Appl. No.: 14/270,429

(22) Filed: May 6, 2014

(51) Int. Cl. H04W 24/10; G01R 21/00

(52) U.S. Cl. CPC H04W 24/10; G01R 21/00

(57) ABSTRACT

Methods implemented in a mobile communication device (e.g., a dual-SIM-dual-active or multi-SIM-multi-active communication device) for improving accuracy of radio-frequency (RF) output power measurements include opportunistically scheduling when a power detector takes RF output power measurements of a radio access technology (“RAT”). In various embodiments, a processor of the mobile communication device may ensure that the power detector takes an accurate RF output power measurement of the RAT by identifying an upcoming time window during which the RAT's transmit power is not artificially reduced as a result of performing transmit blanking/zeroing or artificially increased by transmissions originating from one or more other RATs operating on the device, and configuring or scheduling the power detector to take RF output power measurements of the RAT during that upcoming time window. A priority of the measured RAT may be increased in response to repeated delays in obtaining an RF output power measurement.

### BACKGROUND

Some new designs of mobile communication devices—such as smart phones, tablet computers, and laptop computers—include two or more radio access technologies (“RATs”) that enable the devices to connect to two or more radio access networks. Examples of radio access networks include GSM, TD-SCDMA, CDMA2000, and WCDMA.

Some mobile communication devices that include a plurality of RATs may also include two or more radio-frequency (RF) communication circuits or “RF resources” to provide users with access to multiple separate networks simultaneously. For example, a mobile communication device that includes a plurality of Subscriber Identity Module (“SIM”) cards that are each associated with a different RAT and utilize a different RF resource to connect to a separate mobile telephony network is termed a “multi-SIM-multi-active” or “MSMA” communication device. An example MSMA communication device is a “dual-SIM-dual-active” or “DSDA” communication device, which includes two SIM cards/subscriptions associated with two mobile telephony networks.

A power detector (or “PDET”) operating on a mobile communication device, such as those described in the above examples, measures the transmission power (i.e., the broadband RF output power) of a RAT operating on the device while that RAT is transmitting. More specifically, the power detector may attempt to measure some attribute of the uplink transmission of a RAT by estimating the conductive transmission power at an antenna port on a particular RAT (i.e., a high power or “HDET” measurement) or by measuring the power reflected from an antenna port back to the transmitter components (i.e., an antenna tuner measurement). The power detector is able to take an HDET measurement and an antenna tuner measurement, but not both at the same time.

When a mobile communication device includes a plurality of RATs, each RAT on the device may utilize a different RF resource to communicate with its associated network at any time. For example, a first RAT (e.g., a GSM RAT) may use a first transceiver to transmit to a GSM base station at the same time a second RAT (e.g., a WCDMA RAT) uses a second transceiver to transmit to a WCDMA base station. Typically, a power detector takes measurements of each RAT's transmit power to ensure that each RAT's transmissions are not too strong or too weak. However, because of the proximity of the radios, antennae, etc. of the RF resources included in the mobile communication device, the simultaneous use of the RF resources may cause one or more RF resources to interfere with the ability of the power detector to take accurate transmit RF output power measurements. These interference events (sometimes referred to as “transmission concurrence events”) present a design and operational challenge for multi-radio devices, such as MSMA communication devices, due to the necessary proximity of transmitters in these devices.

### SUMMARY

Various embodiments provide methods, devices, and non-transitory processor-readable storage media for measuring transmitter power of a radio access technology (RAT) operating on a mobile communication device.

Some embodiments methods may include identifying an upcoming time window for taking a radio-frequency (RF) output power measurement of the RAT with a power detector, determining whether the upcoming time window is suitable for taking an accurate RF output power measurement of the RAT, and configuring the power detector to take an RF output power measurement of the RAT during the upcoming time window in response to determining that the upcoming time window is suitable for taking an accurate RF output power measurement of the RAT.

In some embodiments, identifying an upcoming time window for taking an RF output power measurement of the RAT may include identifying an upcoming time window during which the RAT is scheduled to transmit at a consistent RF output power level.

In some embodiments, determining whether the upcoming time window is suitable for taking an accurate RF output power measurement of the RAT may include determining a composite transmission profile for at least one other RAT during the upcoming time window, determining whether the composite transmission profile for the at least one other RAT has a low duty cycle, and determining whether the power detector is able to take an RF output power measurement of the RAT during a transmission gap of the at least one other RAT in the upcoming time window in response to determining that the composite transmission profile has a low duty cycle, and configuring the power detector to take an RF output power measurement of the RAT during the upcoming time window may include configuring the power detector to take an RF output power measurement of the RAT during the transmission gap of the at least one other RAT in the upcoming time window in response to determining that the power detector is able to take an RF output power measurement of the RAT during the transmission gap of the at least one other RAT.

In some embodiments, the methods may also include determining a period of time since a last RF output power measurement of the RAT was taken and raising a priority of the RAT during the upcoming time window in response to determining that the period of time since the last RF output power measurement of the RAT exceeds a threshold amount of time. In such embodiments, determining whether the upcoming time window is suitable for taking an accurate RF output power measurement of the RAT may include determining whether the upcoming time window is suitable for taking an accurate RF output power measurement for the RAT based on the priority of the RAT during the upcoming time window.

In some embodiments, the methods may also include determining whether a threshold number of total attempts to take an RF output power measurement for the RAT has been reached in response to determining that the upcoming time window is not suitable for taking an accurate RF output power measurement of the RAT, and identifying another upcoming time window for taking an RF output power measurement of the RAT in response to determining that the threshold number of total attempts to take an RF output power measurement for the RAT has not been reached.

In some embodiments, determining whether the upcoming time window is suitable for taking an accurate RF output power measurement of the RAT may include determining a transmission schedule for the RAT during the upcoming time window, determining whether the RAT is scheduled to perform transmit blanking during the upcoming time window, determining a transmission schedule of at least one other RAT during the upcoming time window, and determining whether the at least one other RAT is scheduled to transmit during the upcoming time window, in which configuring the power detector to take an RF output power measurement of the RAT during the upcoming time window may include configuring the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

In some embodiments, determining whether the upcoming time window is suitable for taking an accurate RF output power measurement of the RAT may also include determining whether transmissions of the at least one other RAT will adversely affect an RF output power measurement of the RAT during the upcoming time window based on an aggregate intended transmit power of the at least one other RAT during the upcoming time window and an intended transmit power of the RAT during the upcoming time window, with this determination made in response to determining that the at least one other RAT is scheduled to transmit during the upcoming time window, and configuring the power detector to take an RF output power measurement of the RAT during the upcoming time window may also include configuring the power detector to take an RF output power measurement of the RAT during the upcoming time window in response to determining that the RAT is not scheduled to perform transmit blanking during the upcoming time window and that the transmissions of the at least one other RAT will not adversely affect an RF output power measurement of the RAT during the upcoming time window.

In some embodiments, the methods may include determining whether a number of unsuccessful attempts to identify a suitable upcoming time window exceeds a threshold and raising a priority of the RAT during the upcoming time window in response to determining that the number of unsuccessful attempts to identify a suitable upcoming time window exceeds the threshold, in which determining whether the upcoming time window is suitable for taking an accurate RF output power measurement of the RAT may include determining whether the upcoming time window is suitable for taking an accurate RF output power measurement for the RAT based on the priority of the RAT during the upcoming time window.

In some embodiments, the methods may include determining a composite transmission profile for at least one other RAT during the upcoming time window and determining whether the composite transmission profile for the at least one other RAT has a low duty cycle, in which raising a priority of the RAT during the upcoming time window may include immediately raising the priority of the RAT during the upcoming time window in response to determining that the composite transmission profile for the at least one other RAT does not have a low duty cycle.

In some embodiments, determining whether the upcoming time window is suitable for taking an accurate RF output power measurement for the RAT based on the priority of the RAT during the upcoming time window may include determining the priority of the RAT during the upcoming time window, determining a transmission schedule of the RAT during the upcoming time window based on the determined priority of the RAT, determining whether the RAT is scheduled to perform transmit blanking during the upcoming time window, determining a transmission schedule of at least one other RAT during the upcoming time window based on the determined priority of the RAT, and determining whether the at least one other RAT is scheduled to transmit during the upcoming time window, and configuring the power detector to take an RF output power measurement of the RAT during the upcoming time window may include configuring the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

In some embodiments, determining whether the upcoming time window is suitable for taking an accurate RF output power measurement for the RAT based on the priority of the RAT during the upcoming time window may also include determining whether transmissions of the at least one other RAT will adversely affect an RF output power measurement of the RAT during the upcoming time window based on an aggregate intended transmit power of the at least one other RAT during the upcoming time window and an intended transmit power of the RAT during the upcoming time window, with this determination made in response to determining that the at least one other RAT is scheduled to transmit during the upcoming time window, and configuring the power detector to take an RF output power measurement of the RAT during the upcoming time window may also include configuring the power detector to take an RF output power measurement of the RAT during the upcoming time window in response to determining that the RAT is not scheduled to perform transmit blanking during the upcoming time window and that the transmissions of the at least one other RAT will not adversely affect an RF output power measurement of the RAT during the upcoming time window.

Various embodiments may include a mobile communication device configured with processor-executable instructions to perform operations of the methods described above.

Various embodiments may include a mobile communication device having means for performing functions of the operations of the methods described above.

Various embodiments may include non-transitory processor-readable media on which are stored processor-executable instructions configured to cause a processor of a mobile communication device to perform operations of the methods described above.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a communication system block diagram of mobile telephony networks suitable for use with various embodiments.

FIG. 2 is a component block diagram of a mobile communication device according to various embodiments.

FIG. 3 is a component block diagram illustrating interactions between components of different transmit chains in a mobile communication device according to various embodiments.

FIG. 4 is a timeline diagram illustrating a mobile communication device processor's attempts to identify an upcoming time window that is suitable for taking an RF output power measurement of a RAT according to various embodiments.

FIG. 5 is a timeline diagram illustrating a RAT performing Tx blanking.

FIG. 6 is a process flow diagram illustrating a method for configuring a power detector to take an RF output power measurement of a measured RAT during a suitable upcoming time window according to various embodiments.

FIG. 7 is a process flow diagram illustrating a method for determining whether an upcoming time window is suitable for taking an RF output power measurement of a measured RAT according to various embodiments.

FIG. 8 is a process flow diagram illustrating a method for configuring a power detector to take an RF output power measurement of a RAT during an identified upcoming time window based on the RAT's priority according to various embodiments.

FIG. 9 is a process flow diagram illustrating a method for determining whether an upcoming time window is suitable for taking an RF output power measurement of a RAT based on the RAT's priority according to various embodiments.

FIG. 10 is a process flow diagram illustrating a method for configuring a power detector to take an RF output power measurement of a RAT during an identified upcoming time window based on a composite transmission profile of one or more other RATs during an identified upcoming time window according to various embodiments.

FIG. 11 is a process flow diagram illustrating a method for determining whether an upcoming time window is suitable for taking an RF output power measurement of a measured RAT when a composite transmission profile of at least one other RAT during the upcoming time window has a low duty cycle according to various embodiments.

FIG. 12 is a component block diagram of a mobile communication device suitable for implementing some embodiment methods.

### DETAILED DESCRIPTION

Various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

As used herein, the term “mobile communication device” refers to any one or all of cellular telephones, smart phones, personal or mobile multi-media players, personal data assistants, laptop computers, personal computers, tablet computers, smart books, palm-top computers, wireless electronic mail receivers, multimedia Internet enabled cellular telephones, wireless gaming controllers, and similar personal electronic devices that include a programmable processor, memory, and circuitry for connecting to at least two mobile communication networks. Various embodiments may be useful in mobile communication devices, such as smart phones, and so such devices are referred to in the descriptions of various embodiments. However, various embodiments may be useful in any electronic devices that may individually maintain a plurality of RATs that utilize a plurality of separate RF resources, such as MSMA and DSDA communication devices.

As described, transmitter concurrence between two or more RATs operating on a mobile communication device may negatively affect the ability of a power detector to take accurate transmitter power measurements for those RATs. Specifically, a power detector operating on such a mobile communication device may be unable to take accurate RF output power measurements of a particular RAT of interest (herein referred to as the “measured RAT”) when one or more other RATs that are not being measured (herein referred to as “non-measured RATs”) on the device are currently transmitting. This is because the one or more non-measured RATs' transmissions may be picked up by the power detector and included in the power detector's measurements of the measured RAT's transmitter power. Thus, transmitter concurrence may prevent the power detector from reliably determining the measured RAT's individual transmitter power.

The power detector may be unable to accurately measure a particular RAT's RF output power while the measured RAT is configured to reduce or zero its transmitter power in order to mitigate de-sensing one or more non-measured RATs operating on the same mobile communication device (i.e., while the measured RAT is performing “Tx blanking”). This problem is caused by procedures that may be implemented in a mobile communication device to mitigate interference between RATs when one RAT (referred to as the “aggressor RAT”) is attempting to transmit while another RAT (referred to as the “victim RAT”) is simultaneously attempting to receive transmissions. De-sensing may occur when the aggressor RAT is transmitting at the same time that the victim RAT is receiving, in which case the victim RAT may suffer severe impairment to its ability to receive transmissions and may significantly degrade the victim RAT's receiver sensitivity, voice call quality and data throughput. To solve this problem, some mobile communication devices (e.g., DSDA communication devices) implement a process that temporarily blocks or reduces the power of transmissions by the aggressor RAT, which is referred to as transmission (“Tx”) blanking, so that the victim RAT can receive without suffering se-sense. While Tx blanking can solve the problems of de-sensing, if Tx blanking is implemented at the same time that the power detector attempts to measure the RF output power of that RAT (i.e., the aggressor RAT), the result will be an inaccurate RF output power measurement.

Various embodiments provide methods implemented in a mobile communication device (e.g., a DSDA or MSMA communication device) for improving the accuracy of RF output power measurements by opportunistically scheduling when a power detector takes RF output power measurements of a measured RAT. In various embodiments, a processor of the mobile communication device may ensure that the power detector takes an accurate RF output power measurement of the measured RAT by identifying an upcoming time window during which the measured RAT's transmit power will not be artificially reduced as a result of performing Tx blanking or artificially increased substantially by transmissions from one or more non-measured RATs operating on the device, and by configuring the power detector to take RF output power measurements of the measured RAT during that upcoming time window. Thus, various embodiments may improve the accuracy of RF output power measurements taken of the measured RAT, thereby providing an overall increase in the quality and effectiveness of the measured RAT's transmissions because any adjustments to the measured RAT's transmitter power may be based on accurate RF output power measurements. Further, various embodiments enable the measurement of both phase and amplitude of the transmit power; however, for ease of reference, measurements of transmit phase and amplitude are referred to herein as simply measurements of “transmit power.”

In some embodiments in which at least one non-measured RAT is scheduled to transmit during an upcoming time window, the device processor may determine whether transmissions of the at least one non-measured RAT will adversely affect a power measurement of the measured RAT (e.g., as measured by a power detector) during the upcoming time window based on an aggregate of the intended transmit power of the at least one non-measured RAT during the upcoming time window and the intended transmit power of the measured RAT during the upcoming time window. In response to determining that the transmissions of the at least one non-measured RAT will not adversely affect a power measurement of the measured RAT during the upcoming time window, the device processor may determine that the upcoming time window is suitable for taking a power measurement despite the transmissions from the at least one non-measured RAT because the artificial increase in the measured RAT's transmit power may be relatively small and, thus, may not adversely affect the power measurement for the measured RAT.

In some embodiments, the device processor may raise the priority of the measured RAT for the purposes of scheduling transmissions during the next upcoming window in response to failing to identify an upcoming time window that is suitable for taking accurate RF output power readings of the measured RAT (e.g., after a threshold number of attempts and/or after a threshold amount of time has elapsed since the last successful power measurement of the RAT). Raising the priority of the measured RAT may increase the likelihood that the measured RAT will transmit normally during the upcoming time window and that any non-measured RATs on the same mobile communication device will not transmit during that time (e.g., because Tx blanking may be imposed on the non-measured RATs) or that the non-measured RATs will be configured to transmit with a reduced power to avoid affecting (or substantially affecting) the measured RAT's power measurement. For example, the device processor (such as a coexistence management unit implemented as a software module/application) or another component (such as a coexistence management unit implemented as a hardware component) may configure one or more non-measured RATs transmitting during the upcoming time window to perform Tx blanking or reduce their transmit power based on a comparison of those RATs' priorities and the measured RAT's priority. Similarly, in situations in which the measured RAT is scheduled to perform Tx blanking during an upcoming time window for the benefit of one or more victim RATs, the processor/coexistence management unit may prevent the measured RAT from performing Tx blanking during the upcoming time window when the measured RAT has a higher priority than the one or more victim/non-measured RATs. Thus, the device processor may adjust the measured RAT's priority to increase the likelihood (or to ensure) that there will be a suitable upcoming time window available for measuring the measured RAT's transmit power.

In some embodiments, the device processor may account for the transmission characteristics of the one or more non-measured RATs during the upcoming time window and may selectively raise the measured RAT's priority based on those transmission characteristics. For example, if the composite transmitter profile of the one or more non-measured RATs during an upcoming time window has a high duty cycle, such as when the one or more non-measured RATs perform/utilize frequency-divisional duplexing or “FDD,” the one or more non-measured RATs may transmit constantly or nearly constantly, thereby preventing the power detector from taking accurate RF output power measurements of the measured RAT during this time window (or, possibly, the foreseeable future). To address this situation, the device processor may immediately raise the priority of the measured RAT in response to determining that the composite transmission profile of the one or more non-measured RATs has a high duty cycle. This rise in priority may increase the likelihood that the one or more non-measured RATs will not transmit during the upcoming time window, thereby increasing the chances that the upcoming time window will be suitable for taking an RF output power measurement of the measured RAT.

In some embodiments, the device processor may make one or more attempts to identify an available upcoming time window before raising the measured RAT's priority in response to determining that the composite transmitter profile of the one or more non-measured RATs has a low duty cycle. It could be the case that the composite transmission profile of the non-measured RATs during the upcoming time window has a low duty cycle. For example, the non-measured RATs may employ time-divisional duplexing or “TDD.” Because a low-duty-cycle profile may indicate that the non-measured RATs' transmissions are time-based and generally predictable, the device processor may be able to schedule the power detector to take an RF output power measurement during the upcoming time window without automatically raising the measured RAT's priority. For example, when the non-measured RATs have a periodic or predictable transmission schedule (e.g., transmission bursts that occur one out of every eight frames), the device processor may be able to find a transmission gap in the upcoming time window, during which the power detector may take an accurate measurement of the measured RAT's transmit power.

While various embodiments are generally described with reference to improving a power detector's ability to take accurate transmitter power measurements of a measured RAT in light of transmission concurrences between the measured RAT and one or more non-measured RATs, the embodiments may similarly improve the power detector's ability to take accurate transmitter power measurements of the measured RAT in light of transmission concurrences between the measured RAT and other radios operating on the same mobile communication device, such as a Wi-Fi radio, Bluetooth radio, etc.

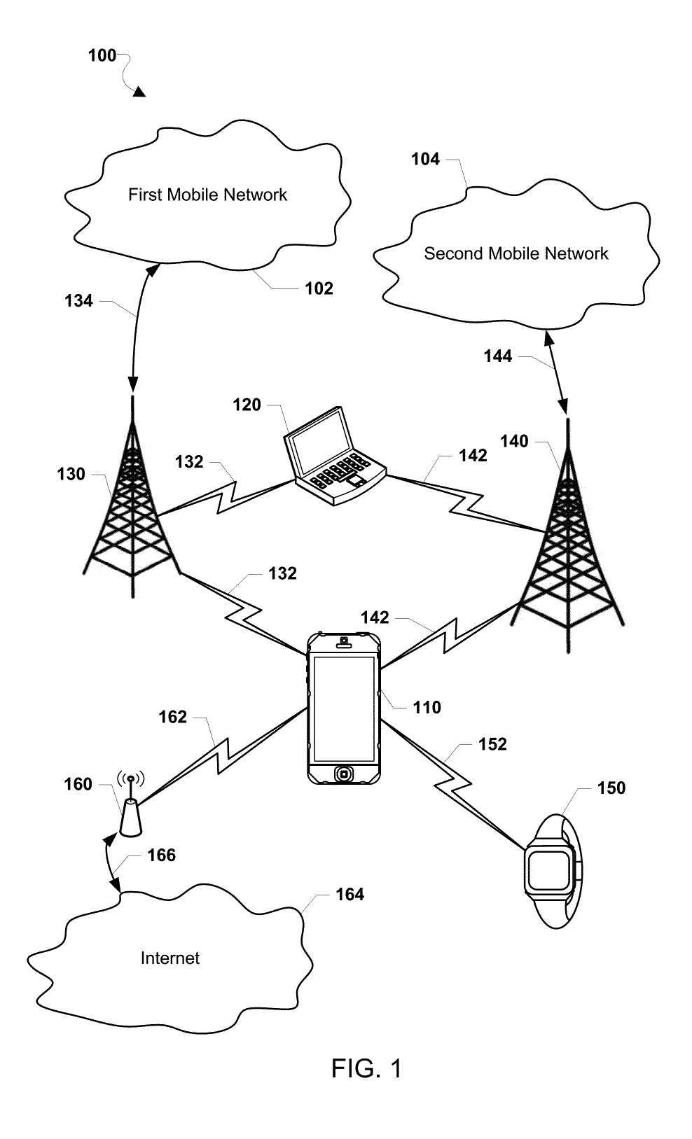

Various embodiments may be implemented within a variety of communication systems 100, such as at least two mobile telephony networks, an example of which is illustrated in FIG. 1. A first mobile network 102 and a second mobile network 104 typically each include a plurality of cellular base stations (e.g., a first base station 130 and a second base station 140). A first mobile communication device 110 may be in communication with the first mobile network 102 through a cellular connection 132 to the first base station 130. The first mobile communication device 110 may also be in communication with the second mobile network 104 through a cellular connection 142 to the second base station 140. The first base station 130 may be in communication with the first mobile network 102 over a wired connection 134. The second base station 140 may be in communication with the second mobile network 104 over a wired connection 144.

A second mobile communication device 120 may similarly communicate with the first mobile network 102 through the cellular connection 132 to the first base station 130. The second mobile communication device 120 may also communicate with the second mobile network 104 through the cellular connection 142 to the second base station 140. The cellular connections 132 and 142 may be made through two-way wireless communication links, such as 4G, 3G, CDMA, TDMA, WCDMA, GSM, and other mobile telephony communication technologies.

While the mobile communication devices 110, 120 are shown connected to two mobile networks 102, 104, in some embodiments (not shown), the mobile communication devices 110, 120 may include two or more subscriptions to two or more mobile networks and may connect to those subscriptions in a manner similar to those described above.

In some embodiments, the first mobile communication device 110 may establish a wireless connection 152 with a peripheral device 150 used in connection with the first mobile communication device 110. For example, the first mobile communication device 110 may communicate over a Bluetooth® link with a Bluetooth-enabled personal computing device (e.g., a “smart watch”). In some embodiments, the first mobile communication device 110 may establish a wireless connection 162 with a wireless access point 160, such as over a Wi-Fi connection. The wireless access point 160 may be configured to connect to the Internet 164 or another network over a wired connection 166.

While not illustrated, the second mobile communication device 120 may similarly be configured to connect with the peripheral device 150 and/or the wireless access point 160 over wireless links.

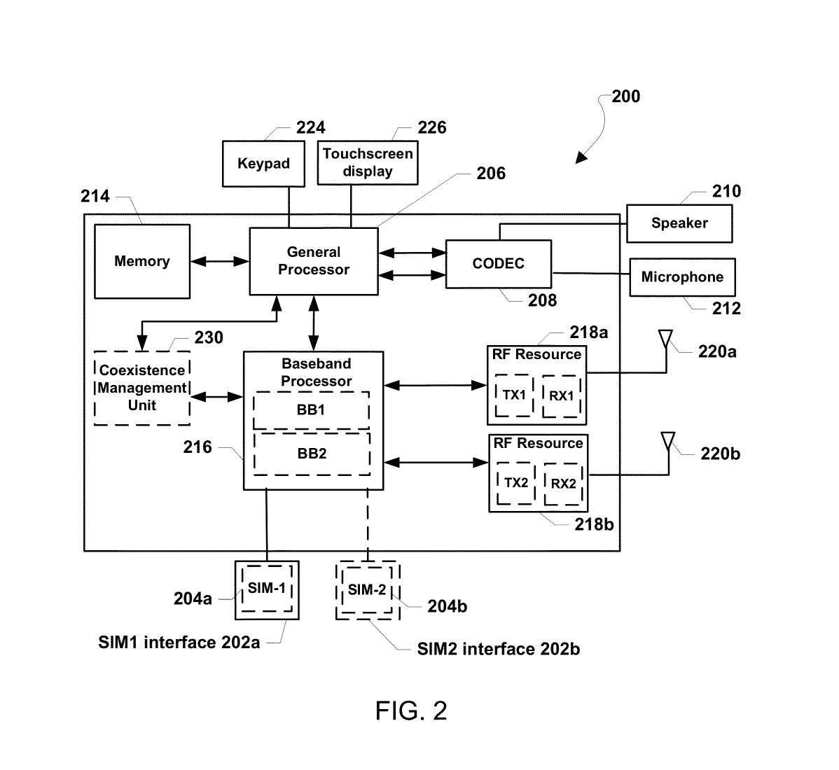

FIG. 2 is a functional block diagram of a mobile communication device 200 suitable for implementing various embodiments. According to various embodiments, the mobile communication device 200 may be similar to one or more of the mobile communication devices 110, 120 as described with reference to FIG. 1. With reference to FIGS. 1-2, the mobile communication device 200 may include a first SIM interface 202a, which may receive a first identity module SIM-1 204a that is associated with a first subscription. The mobile communication device 200 may optionally also include a second SIM interface 202b, which may receive a second identity module SIM-2 204b that is associated with a second subscription.

A SIM in various embodiments may be a Universal Integrated Circuit Card (UICC) that is configured with SIM and/or USIM applications, enabling access to GSM and/or UMTS networks. The UICC may also provide storage for a phone book and other applications. Alternatively, in a CDMA network, a SIM may be a UICC removable user identity module (R-UIM) or a CDMA subscriber identity module (CSIM) on a card. A SIM card may have a CPU, ROM, RAM, EEPROM and I/O circuits. An Integrated Circuit Card Identity (ICCID) SIM serial number may be printed on the SIM card for identification. However, a SIM may be implemented within a portion of memory of the mobile communication device, and thus need not be a separate or removable circuit, chip or card.

A SIM used in various embodiments may contain user account information, an international mobile subscriber identity (IMSI), a set of SIM application toolkit (SAT) commands and other network provisioning information, as well as provide storage space for phone book database of the user's contacts. As part of the network provisioning information, a SIM may store home identifiers (e.g., a System Identification Number (SID)/Network Identification Number (NID) pair, a Home PLMN (HPLMN) code, etc.) to indicate the SIM card network operator provider. An Integrated Circuit Card Identity (ICCID) SIM serial number is printed on the SIM card for identification.

The mobile communication device 200 may include at least one controller, such as a general purpose processor 206, which may be coupled to a coder/decoder (CODEC) 208. The CODEC 208 may in turn be coupled to a speaker 210 and a microphone 212. The general purpose processor 206 may also be coupled to at least one memory 214. The memory 214 may be a non-transitory computer readable storage medium that stores processor-executable instructions. For example, the instructions may include routing communication data relating to the first or second subscription though a corresponding baseband-RF resource chain.

The memory 214 may store an operating system (OS), as well as user application software and executable instructions. The memory 214 may also store application data, such as an array data structure.

The general purpose processor 206 and the memory 214 may each be coupled to at least one baseband modem processor 216. Each SIM and/or RAT in the mobile communication device 200 (e.g., SIM-1 204a and SIM-2 204b) may be associated with a baseband-RF resource chain. A baseband-RF resource chain may include the baseband modem processor 216, which may perform baseband/modem functions for communicating with/controlling a RAT, and may include one or more amplifiers and radios, referred to generally herein as RF resources (e.g., RF resources 218a, 218b). In some embodiments, baseband-RF resource chains may share the baseband modem processor 216 (i.e., a single device that performs baseband/modem functions for all RATs on the wireless device). In other embodiments, each baseband-RF resource chain may include physically or logically separate baseband processors (e.g., BB1, BB2).

The RF resources 218a, 218b may each be transceivers associated with one or more RATs and may perform transmit/receive functions for the wireless device on behalf of their respective RATs. For example, a first RAT (e.g., a GSM RAT) may be associated with an RF resource 218a, and a second RAT (e.g., a CDMA or WCDMA RAT) may be associated with an RF resource 218b. The RF resources 218a, 218b may include separate transmit and receive circuitry, or may include a transceiver that combines transmitter and receiver functions. The RF resources 218a, 218b may each be coupled to a wireless antenna (e.g., a first wireless antenna 220a or a second wireless antenna 220b). The RF resources 218a, 218b may also be coupled to the baseband modem processor 216.

In some embodiments, the general purpose processor 206, the memory 214, the baseband processor(s) 216, and the RF resources 218a, 218b may be included in the mobile communication device 200 as a system-on-chip. In some embodiments, the first and second SIMs 204a, 204b and their corresponding interfaces 202a, 202b may be external to the system-on-chip. Further, various input and output devices may be coupled to components on the system-on-chip, such as interfaces or controllers. Example user input components suitable for use in the mobile communication device 200 may include, but are not limited to, a keypad 224, a touchscreen display 226, and the microphone 212.

In some embodiments, the keypad 224, the touchscreen display 226, the microphone 212, or a combination thereof, may perform the function of receiving a request to initiate an outgoing call. For example, the touchscreen display 226 may receive a selection of a contact from a contact list or receive a telephone number. In another example, either or both of the touchscreen display 226 and the microphone 212 may perform the function of receiving a request to initiate an outgoing call. For example, the touchscreen display 226 may receive selection of a contact from a contact list or to receive a telephone number. As another example, the request to initiate the outgoing call may be in the form of a voice command received via the microphone 212. Interfaces may be provided between the various software modules and functions in the mobile communication device 200 to enable communication between them, as is known in the art.

Functioning together, the two SIMs 204a, 204b, the baseband processor BB1, BB2, the RF resources 218a, 218b, and the wireless antennas 220a, 220b may constitute two or more RATs. For example, a SIM, baseband processor, and RF resource may be configured to support two different RATs. More RATs may be supported on the mobile communication device 200 by adding more SIM cards, SIM interfaces, RF resources, and antennae for connecting to additional mobile networks.

The mobile communication device 200 may include a coexistence management unit 230 configured to manage and/or schedule the RATs' utilization of the RF resources 218a, 218b. As described, the coexistence management unit 230 may be implemented as a software module implemented on the general purpose processor 206 or the baseband modem processor 216, as a separate hardware component, or as a combination of hardware and software. The coexistence management unit 230 may configure one or more non-measured RATs to perform Tx blanking during an upcoming time window to enable a power detector (not shown) to take an accurate measurement of a measured RAT's transmit power.

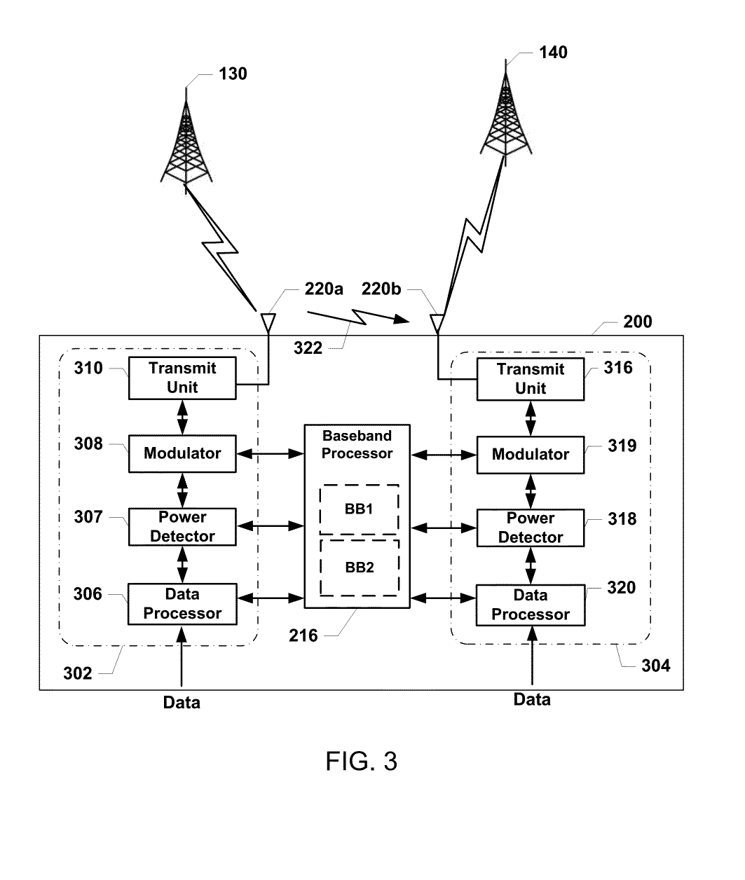

FIG. 3 illustrates a block diagram 300 of transmit components in separate RF resources on the mobile communication device 200, as described with reference to FIGS. 1-2 according to various embodiments. With reference to FIGS. 1-3, for example, a first transmitter 302 may be part of the RF resource 218a associated with a first RAT (not shown), and a second transmitter 304 may be part of the RF resource 218b and associated with a second RAT (not shown). In particular embodiments, the first transmitter 302 may include a data processor 306 that may format, encode, and interleave data to be transmitted. The first transmitter 302 may include a modulator 308 that modulates a carrier signal with encoded data, for example, by performing Gaussian minimum shift keying (GMSK). One or more transmit units 310 may condition the modulated signal (e.g., by filtering, amplifying, and upconverting) to generate an RF modulated signal for transmission. The RF modulated signal may be transmitted, for example, to the first base station 130 via the first wireless antenna 220a. The first transmitter 302 may also include a power detector 307 for measuring the first RAT's transmit power.

The second transmitter 304 may similarly include the wireless antenna 220b, a data processor 320, a modulator 319, and a transmit unit 316 for transmitting RF modulated signals to the second base station 140 as described with reference to the first transmitter 302. The second transmitter 304 may also include a power detector 318 configured to measure one or more aspects of the transmit power of the second RAT associated with the second transmitter 304.

As noted, a RAT's transmit power may need to be adjusted to maintain a satisfactory connection with its network. For example, as a mobile communication device 200 continues moving away from a base station (e.g., the first base station 130) on which a first RAT is camped, the first RAT may need to continually increase its transmit power to maintain a satisfactory connection. In a further example, if the mobile communication device 200 moves too far away from the first base station 130, the RAT may perform a reselection operation and may camp on another base station (not shown) that is closer. As a result, the RAT's transmit power may be scaled back without sacrificing the connection quality because the new base station is considerably closer than its former base station (e.g., the first base station 130).

In an example, the power detector 318 may take measurements of the second RAT's transmit power in order to ensure that the signals sent from the second transmitter 304 to the second base station 140 are not too strong or too weak. For example, the power detector 318 may measure the second RAT's total broadband RF output power at the second wireless antenna 220b by taking high-power or “HDET” measurements and/or antenna tuner measurements. In a further example, the power detector 318, alone or with one or more components operating on the mobile communication device 200 (e.g., the baseband modem processor 216), may measure the broadband RF output powers of the second RAT by taking an analog power reading of the second RAT's broadband RF output power, converting the measured broadband RF output power to a DC voltage value, and converting the DC voltage value into a digital value that indicates incident power and/or the antenna tuner measurement value. Based on these digital values, a processor (e.g., the baseband modem processor 216, the coexistence management unit 230, or the general purpose processor 206) may adjust the transmit powers for the second RAT, if necessary. The power detector 307 may operate similarly with respect to the first RAT.

When transmissions are occurring on both of the transmitters 302, 304, transmissions from the first transmitter 302 (e.g., transmissions 322) may be included in the RF output power measurement of the second transmitter 304 by the power detector 318, and such power may be erroneously attributed to the second RAT's transmit power. As a result of including some of the first RAT's transmissions 322 in the measurement of the second RAT's transmit power, the power detector 318's measurement of the second RAT RF output power may be artificially high. To address this problem, in various embodiments, a processor (e.g., the general purpose processor 206, the baseband modem processor 216, and/or the coexistence management unit 230) of the mobile communication device 200 may perform, for example, one or more embodiment methods described in the disclosure to ensure that the power detector 318 is able to make an accurate RF output power measurement.

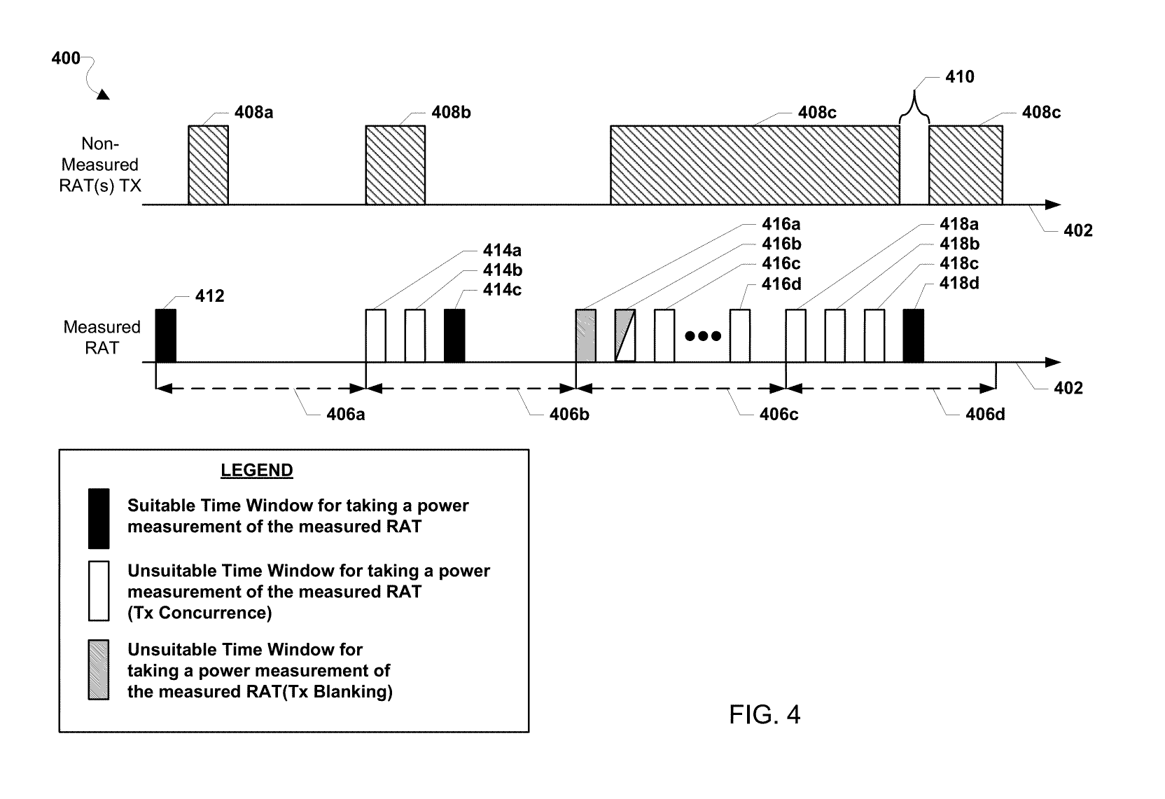

FIG. 4 illustrates a timeline diagram 400 of attempts over time 402 of a device processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) to identify an upcoming time window that is suitable for a power detector (e.g., the power detectors 307, 318 of FIG. 3) taking an accurate RF output power measurement of a measured RAT.

With reference to FIGS. 1-4, in some embodiments, rather than attempting to identify a specific time at which the power detector should take an RF output power measurement of a measured RAT, the device processor may attempt to identify a range of time (i.e., a time window) during which the power detector may take accurate RF output power measurements for a particular RAT (the “measured RAT”). In such embodiments, the device processor may identify an upcoming time window based on when the measured RAT will have stable transmissions in the near future (i.e., transmissions at a consistent RF output power level). In other words, the device processor may select a time window to avoid times during which the measured RAT will be subject to transient (i.e., inconsistent) transmissions characterized by temporary increases or decreases in the measured RAT's transmit power, such as when the measured RAT reselects to a new cell/base station.

The power detector may need to take RF output power measurements of the measured RAT at regular intervals so that the measured RAT's transmit power may be adjusted (e.g., as described with reference to FIG. 3). For example, the power detector may attempt to take an RF output power measurement of the measured RAT during each of time periods 406a-406d, and each of these time periods 406a-406d may be a specific duration based on the characteristics of the measured RAT or based on the current state/mode of the measured RAT. For example when the measured RAT is associated with a WCDMA communication protocol, the measured RAT may attempt to take an RF output power measurement every 10 microseconds, in which case the time periods 406a-406d may be 10 microseconds in length. In other embodiments, output power measurements may be taken at different intervals.

During each of the time periods 406a-406d, the device processor may identify one or more time windows during which the power detector may be able to take an accurate measurement of the measured RAT's transmit power. The device processor may only make a threshold number of attempts to identify a suitable time window (i.e., a time window in which the power detector is capable of taking an accurate power measurement of the measured RAT) during any one of the time period 406a-406d. In response to determining that a threshold number of failed attempts to find a suitable time window has been reached, the device processor may wait until the next time period begins before attempting to identify a suitable time window.

An upcoming time window may not be suitable for the power detector to take an accurate RF output power measurement for one or more reasons. As described, the power detector may be unable to take accurate RF output power measurements of a measured RAT during a time window in which one or more non-measured RATs will be transmitting because any RF output power measurements of the measured RAT during that time window may be corrupted by those other transmissions. In another circumstance, the power detector may be unable to take accurate RF output power measurements during a time window in which the measured RAT will be performing Tx blanking (i.e., reducing/zeroing its transmitter power to benefit a victim RAT), thereby substantially preventing the power detector from taking an accurate measurement of the measured RAT's true/unaltered transmitter power.

In the example illustrated in FIG. 4, the timeline diagram 400 illustrates several example scenarios that may affect the power detector's ability to take a successful/accurate RF output power measurement of the measured RAT during time windows identified by the device processor. During the first time period 406a, the device processor may determine that a time window 412 is suitable for taking one or more accurate RF output power measurements of the measured RAT because a transmission period 408a for one or more non-measured RATs does not coincide with the time window 412 and because the measured RAT is not scheduled to perform Tx blanking during that time. In response to identifying that the time window 412 is suitable for taking an RF output power measurement, the device processor may configure the power detector to take an RF output power measurement during the time window 412. After taking the RF output power measurement in the time window 412, the power detector may not need to take another RF output power measurement of the measured RAT until the next time period (i.e., the time period 406b) starts.

When the time period 406b begins, the device processor may identify a time window 414a that is unsuitable for taking an accurate RF output power measurement of the measured RAT because one or more non-measured RATs are scheduled to transmit during a transmission period 408b that completely (or at least partially) overlaps with the time window 414a (i.e., a transmission concurrence event is occurring). Similarly, the device processor may also determine that a time window 414b is also unsuitable because the transmission period 408b may be continuing throughout the time window 414b. After the transmission period 408b ends, the device processor may identify a suitable time window 414c and may configure the power detector to take an RF output power measurement of the measured RAT during the time window 414c.

In response to determining that another (third) time period 406c has started, the device processor may identify a time window 416a that is unsuitable for taking RF output power measurements of the measured RAT because the measured RAT may be configured to perform Tx blanking during that time. For example, the measured RAT may be configured to stop transmitting during the time window 416a to accommodate a victim RAT's performing high-priority reception activities. As shown in the example illustrated in FIG. 4, the measured RAT may continue performing Tx blanking during a time window 416b, thereby making the time window 416b unsuitable. Further, during the time window 416b, one or more non-measured RATs may be transmitting during a transmission period 408c, further preventing the power detector from making an accurate RF output power measurement of the measured RAT.

The device processor may identify another time window 416c that is unsuitable because, while the measured RAT may no longer be performing Tx blanking, the transmission period 408c may be continuing. The device processor may continue identifying time windows during the third time period 406c until a threshold number of failed attempts to identify a suitable time window has been reached, which may occur, for example, when the device processor identifies that the time window 416d is unsuitable. In the provided example, the threshold number of failed attempts is four. In other embodiments, the threshold number of failed attempts may be set to any suitable number.

In some embodiments, the device processor may maintain an ongoing count or tally of the number of unsuitable time windows that have been identified since the last suitable time window was identified (e.g., the number of unsuitable time windows since time window 414c) and may increase the priority of the measured RAT during an upcoming time window when the total number of identified unsuitable time windows exceeds a threshold number. For example, as illustrated in FIG. 4, after the fourth time period 406d begins, the device processor may identify unsuitable time windows 418a-418c, at which point the processor may determine that a threshold number of unsuitable time windows has been reached. Alternatively, the device processor may determine that the threshold number of unsuitable time windows has been reached when a threshold amount of time since the last RF output measurement was taken has elapsed.

In response to determining that threshold number of unsuitable time windows (or duration since the last measurement) has been reached, the device processor may assign a higher priority to the measured RAT during the upcoming time window 418d. A coexistence management unit (e.g., the coexistence management unit 230) or coexistence manager that manages the transmit and receive windows of two or more RATs may allocate RF resources and implement receive or transmit blanking based on the relative priority of each RAT. Thus, assigning a higher priority to the measured RAT may increase the likelihood that the coexistence management unit will allocate a transmission window to the measured RAT to enable the power detector to take an accurate RF output power measurement of the measured RAT. For example, because the measured RAT will have a higher priority during the upcoming time window 418d, the coexistence manager may not require the measured RAT to perform Tx blanking (i.e., the measured RAT's RF output power measurement may take precedence over potential victim RAT(s)′ activities) and/or the coexistence manager may require the one or more non-measured RATs to perform Tx blanking to prevent their transmissions from corrupting the power detector's measurements during the time window 418d. In some embodiments, rather than configuring the one or more non-measured RATs to perform Tx blanking during the time window 418d, the device processor/coexistence manager may reduce the one or more non-measured RATs' transmit power to a level that may not affect (or may not substantially affect) the measured RAT's power measurements, thereby improving the measured RAT's power measurements while only marginally degrading the non-measured RATs' performance.

Thus, as illustrated in FIG. 4, the transmission period 408c may be interrupted prior to the beginning of the time window 418d, and the transmission period 408c may resume after a period of time 410 corresponding to the time window 418d (i.e., after the power detector is able to make an accurate RF output power measurement of the measured RAT). In response to identifying the suitable time window 418d, the device processor may reset the count of unsuitable time windows (or a timer monitoring the duration since the last RF output power measurement of the measured RAT).

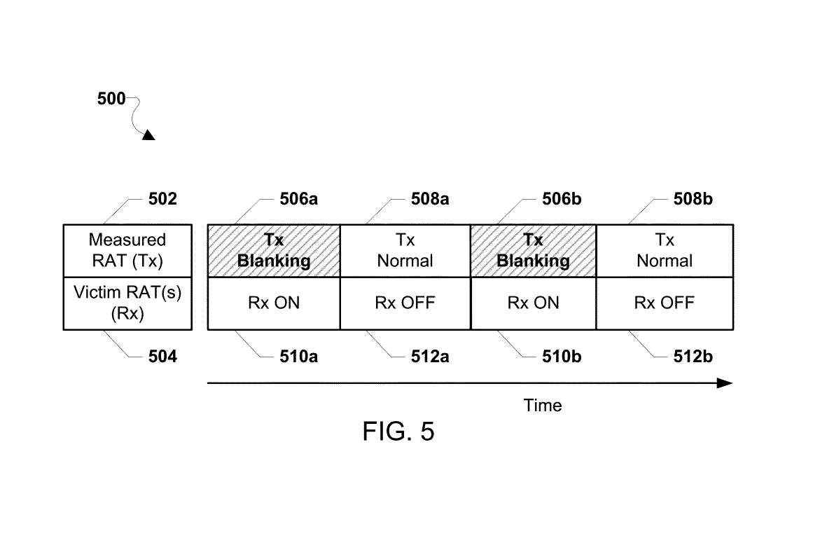

FIG. 5 illustrates timeline diagram 500 describing an example of implementing Tx blanking on a mobile communication device (e.g., the mobile communication device 200 described with reference to FIGS. 1-3). With reference to FIGS. 1-5, a measured RAT 502 may be configured to perform Tx blanking to enable one or more victim RATs 504 to perform RF activities (e.g., receiving and/or transmitting) when the measured RAT 502 would otherwise be transmitting. In an example, the one or more victim RATs 504 may have a higher priority, and a device processor (e.g., the general purpose processor 206, the baseband modem processor 216, the coexistence management unit 230, a separate controller, and/or the like) on the mobile communication device may configure the measured RAT 502 to perform Tx blanking in situations in which the measured RAT 502's transmissions may interfere with, de-sense, or frustrate the reception activities of the one or more victim RATs 504.

Thus, in the example illustrated in FIG. 5, during a period of time in which the one or more victim RATs 504 are receiving transmissions (e.g., receiver periods 510a and 510b), the device processor may configure the measured RAT 502 to perform Tx blanking (e.g., Tx blanking periods 506a and 506b). As described, a power detector (e.g., the power detectors 307, 318) may be unable to obtain an accurate RF output power measurement of the measured RAT 502 during the Tx blanking periods 506a, 506b because the measured RAT 502's transmitter power may be reduced or zeroed during these periods 506a, 506b to accommodate the higher-priority activities occurring on the one or more victim RATs 504.

Similarly, during periods in which the one or more victim RATs 504 are not receiving (e.g., non-receiver periods 512a and 512b), the measured RAT 502 may transmit normally (e.g., transmission periods 508a and 508b), and the power detector may be able to take accurate RF output power measurements of the measured RAT. As described, the device processor may raise the measured RAT 502's priority after one or more unsuccessful attempts to identify a suitable time window, thereby increasing the likelihood that the measured RAT 502 will not be scheduled to perform Tx blanking.

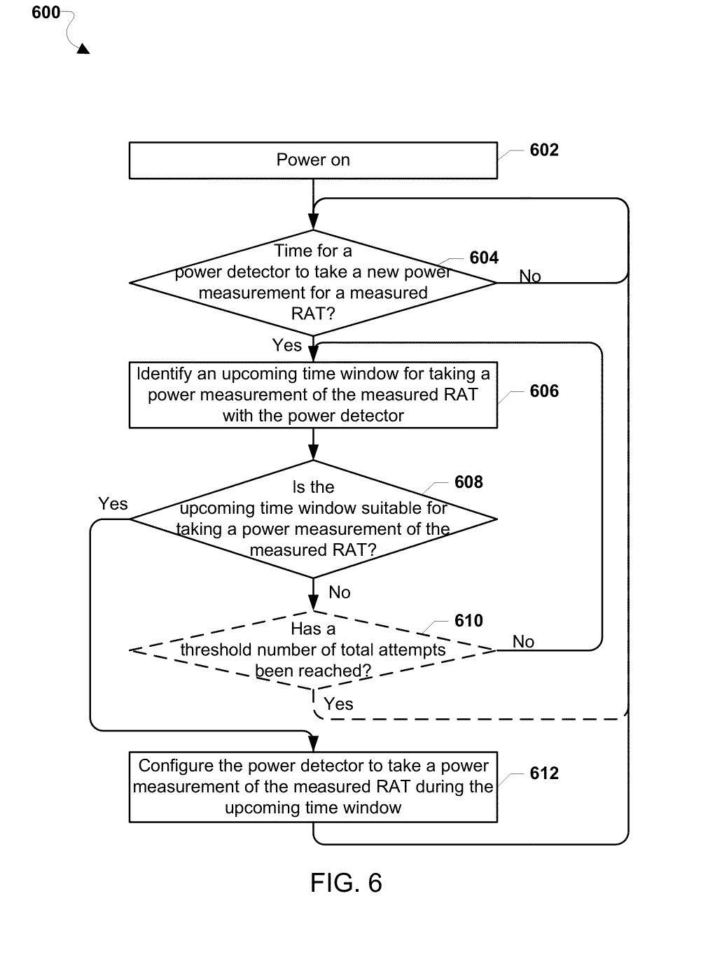

FIG. 6 illustrates a method 600 that may be implemented by a processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) for configuring a power detector to measure the transmitter power of a measured RAT during a suitable upcoming time window. With reference to FIGS. 1-6, after powering on in block 602, the device processor may determine whether it is time for a power detector (e.g., the power detectors 307, 318) to take a new RF output power measurement for a RAT (i.e., the measured RAT) in determination block 604. As discussed, the power detector may be configured to periodically take transmitter power measurements of the measured RAT (e.g., once during each of the time periods 406a-406d), and the measured RAT's transmitter power may be adjusted based on these measurements. For example, when the measured RAT is associated with WCDMA technology, the power detector may need to take RF output power measurements of the measured RAT every 10 milliseconds while the measured RAT is operating in an acquisition mode or once every 100 milliseconds while the measured RAT is operating in a tracking mode. In another example, when the power detector is taking antenna tuner measurements of the measured RAT, the power detector may need to take an RF output power measurement every 50 milliseconds, and the duration of each power measurement may be 300 to 500 microseconds.

In response to determining that it is not time for the power detector to take a new RF output power measurement of the measured RAT (i.e., determination block 604=“No”), the device processor may repeat the operations of determination block 604 in a loop until the device processor determines that it is time for the power detector to take a new RF output power measurement of the measured RAT. For example, the device processor may wait until the beginning of the next time period in which an RF output power measurement is needed.

In response to determining that it is time for the power detector to take a new RF output power measurement of the measured RAT (i.e., determination block 604=“Yes”), the device processor may identify an upcoming time window for taking an RF output power measurement of the measured RAT in block 606, such as by identifying an upcoming period of time in which the transmitter power of the measured RAT is constant and/or steady. For example, the device processor may analyze the measured RAT's current and/or upcoming transmission schedule to determine when the measured RAT's transmitter power is not likely to be changing (e.g., when there is no risk of reselecting to a new cell/base station).

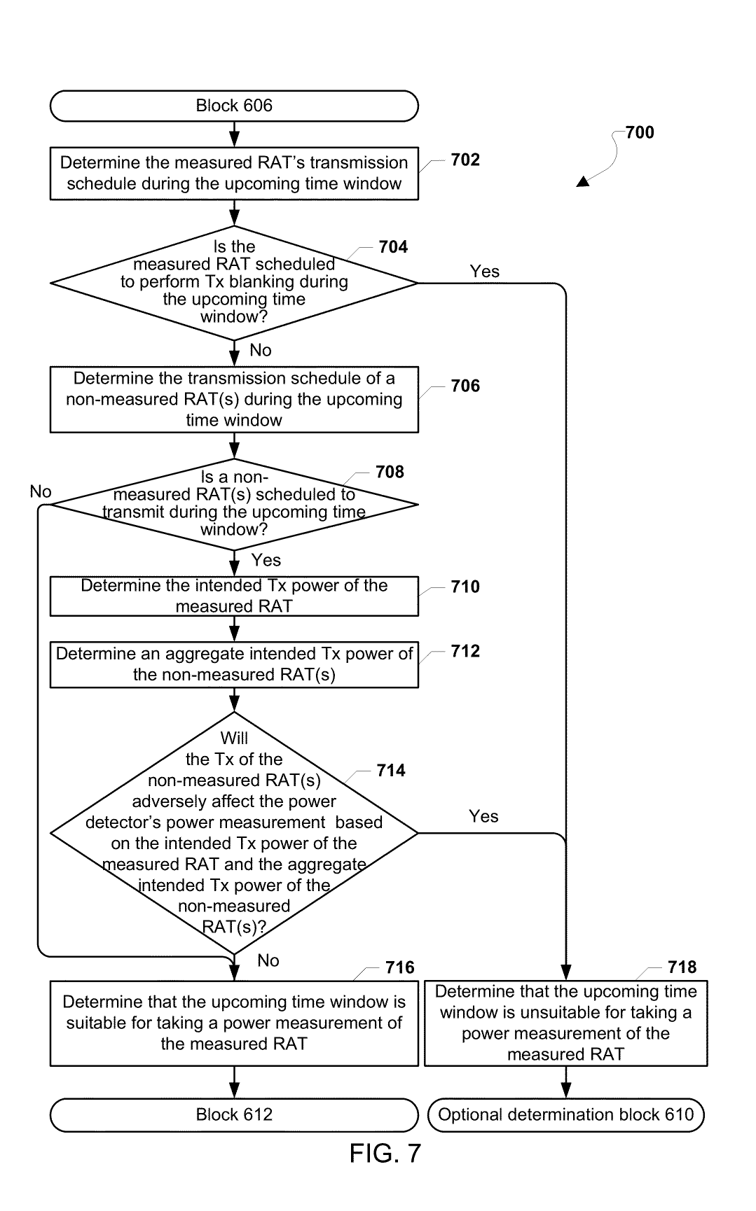

In determination block 608, the device processor may determine whether the upcoming time window is suitable for taking an RF output power measurement of the measured RAT (e.g., as described with reference to FIG. 7). As described, the upcoming time window may be suitable when the power detector is capable of taking an accurate RF output power measurement of the measured RAT during that window (e.g., when the measured RAT is not scheduled to perform Tx blanking and when one or more non-measured RATs are not scheduled to transmit).

In response to determining that the upcoming window is not suitable for taking an RF output power measurement of the measured RAT (i.e., determination block 608=“No”), the device processor may optionally determine whether a threshold number of total attempts to identify a suitable upcoming time window has been reached, in optional determination block 610. In some embodiments, the device processor may only make a certain number of attempts during a time period in which an RF output power measurement is needed (e.g., the time periods 406a-406c) in order to save power and processing resources.

In response to determining that a threshold number of total attempts has been reached (i.e., optional determination block 610=“Yes”), the device processor may again determine whether it is time for a power detector to take a new RF output power measurement for a RAT (i.e., the measured RAT) in determination block 604. For example, a non-measured RAT may be engaged in a high priority/emergency call, making it impossible for the device processor to identify a suitable upcoming time window in the near future. Thus, after making a certain number of failed attempts to identify a suitable upcoming time window, the device processor may temporarily cease its attempts and may wait until the next time that the power detector needs to take an RF output power measurement of the measured RAT in case conditions have changed/improved (e.g., the non-measured RAT has stopped transmitting). In some embodiments, the device processor may also reset/reinitialize the current number of total attempts to identify a suitable upcoming time window on reaching the threshold number of total attempts.

In response to determining that a threshold number of total attempts has not been reached (i.e., optional determination block 610=“No”), the device processor may repeat the operations in block 606 by identifying another upcoming time window for taking an RF output power measurement with the measured RAT.

In response to determining that the upcoming time window is suitable for taking an RF output power measurement of the measured RAT (i.e., determination block 608=“Yes”), the device processor may configure or schedule the power detector to take an RF output power measurement of the measured RAT during the upcoming time window, in block 612. Thus, by identifying a suitable upcoming time window, the power detector may be able to take an accurate measurement of the measured RAT's transmit power, thereby improving the effectiveness of any adjustments made to the measured RAT's transmit power.

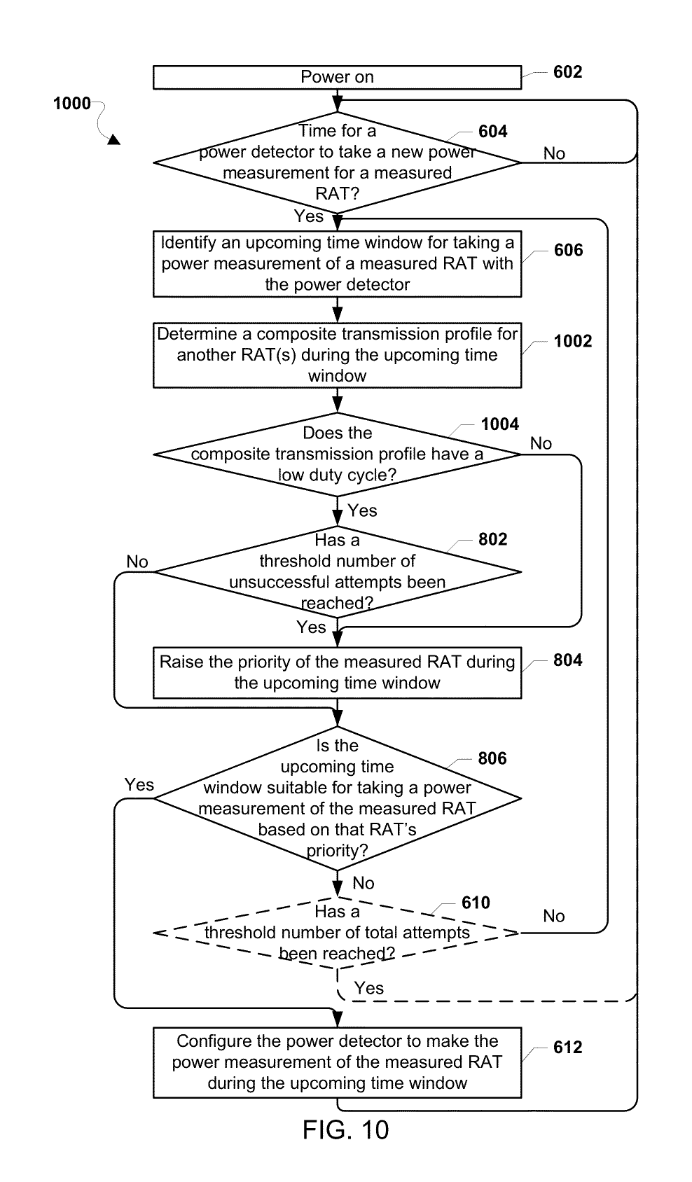

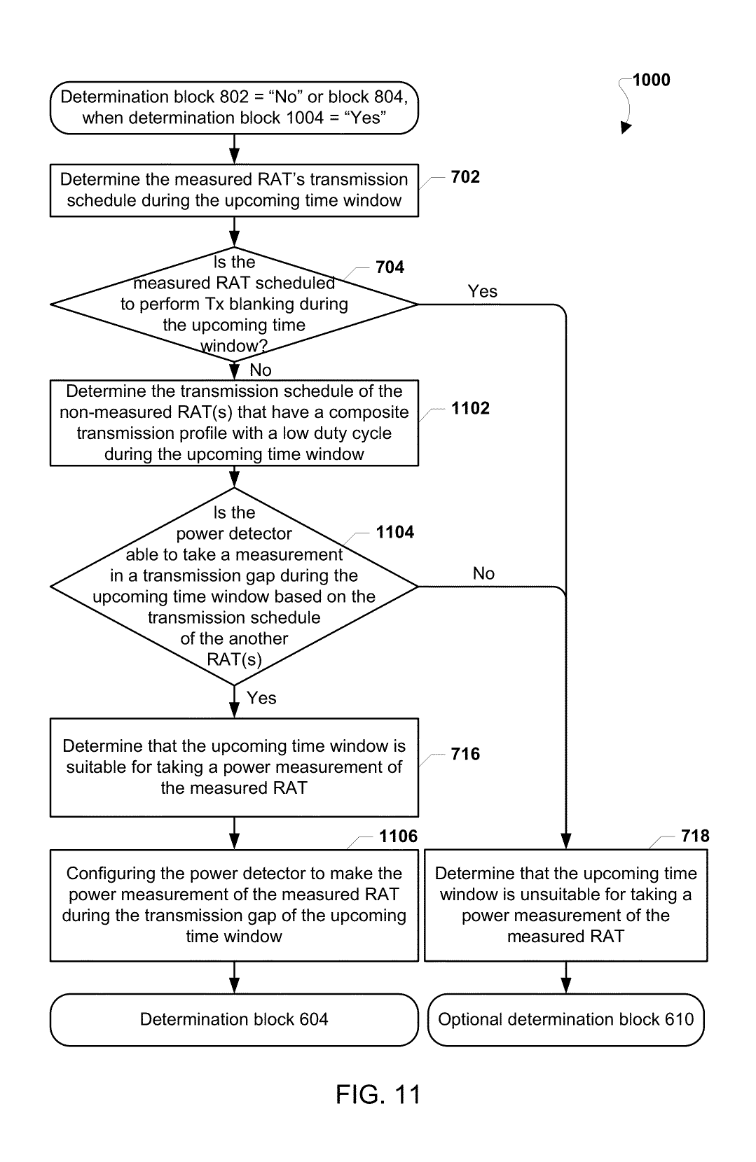

In some embodiments (e.g., as described with reference to FIGS. 10 and 11), the processor device may determine whether an upcoming time window is suitable for taking an RF output power measurement of the measured RAT in determination block 608 by analyzing the composite transmission profile of one or more non-measured RATs during the upcoming time window. If the device processor determines that the composite transmission profile has a low duty cycle characterized by limited transmissions (e.g., time-based, predictable transmissions, such as from RATs utilizing TDD), the device processor may attempt to find a transmission gap in the upcoming gap during which the one or more non-measured RATs are not scheduled to transmit. For example, the device processor may determine that a non-measured GSM RAT will transmit in predictable, time-based bursts during the upcoming time window and that the power detector would have enough time to take an RF output power measurement during that transmission gap. Thus, in response to determining that the power detector can make an RF output power measurement during a transmission gap, the device processor may configure/schedule the power detector in block 612 to make the RF output power measurement of the measured RAT during a transmission gap of the one or more non-measured RATs.

The device processor may repeat the above operations of the method 600 in a continuous loop by returning to determination block 604 to determine whether it is time for the power detector to take another RF output power measurement and proceeding as described.

FIG. 7 illustrates a method 700 that may be implemented by a processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) for determining whether an upcoming time window is suitable for taking an RF output power measurement of a measured RAT. The operations of the method 700 implement some embodiments of the operations in determination block 608 of the method 600 (refer to FIG. 6). Thus, with reference to FIGS. 1-7, the device processor may begin performing the operations of the method 700 in response to identifying an upcoming time window for making an RF output power measurement with the measured RAT in block 606 of the method 600.

In block 702, the device processor may determine the measured RAT's transmission schedule during an upcoming time window, such as by receiving the schedule from the measured RAT's mobile network, from a scheduler, and/or by predicting the measured RAT's transmissions during the upcoming time window based on the measured RAT's previous transmission patterns or other observations.

In determination block 704, the device processor may also determine whether the measured RAT is scheduled to perform Tx blanking during the upcoming time window. In some embodiments, the device processor may obtain this information from a coexistence manager (e.g., the coexistence management unit 230) operating on the processor, or may independently determine this by accessing a priority listing for each RAT on the mobile communication device and determining whether the priority of a non-measured RAT may (or will) cause the measured RAT to perform Tx blanking during the upcoming time window. For example, a higher-priority, non-measured RAT may be scheduled to perform discontinuous reception during the upcoming time window, in which case, the measured RAT will likely be scheduled to perform Tx blanking to accommodate a higher priority RAT.

In response to determining that the measured RAT is scheduled to perform Tx blanking during the upcoming time window (i.e., determination block 704=“Yes”), the device processor may determine that the upcoming time window is unsuitable for taking an RF output power measurement of the measured RAT, in block 718, because it is unlikely or impossible for the power detector to take an accurate RF output power measurement while the measured RAT's transmit power is reduced/zeroed. The processor may optionally determine whether a threshold number of total attempts to identify a suitable upcoming window has been reached in optional determination block 610 and may continue to execute the operations of the method 600 as described.

In response to determining that the measured RAT is not scheduled to perform Tx blanking during the upcoming time window (i.e., determination block 704=“No”), the device processor may determine the transmission schedule of one or more non-measured RATs during the upcoming time window, in block 706, such as by performing operations similar to those described with reference to block 702.

In determination block 708, the device processor may determine whether one or more non-measured RATs are scheduled to transmit during the upcoming time window based on their transmission schedules determined in block 706. In response to determining that one or more non-measured RATs are scheduled to transmit during the upcoming time window (i.e., determination block 708=“Yes”), the device processor may determine the intended transmit power of the measured RAT during the upcoming time window in block 710, such as by estimating an expected transmit power that may enable the measured RAT to acquire service with a sufficient or desired quality of service. In some embodiments, the device processor may determine the intended transmit power based on a history of the measured RAT's transmit powers, based on information received from the measured RAT's network, based on transmit power values preloaded on the mobile communication device (e.g., by an original equipment manufacturer), etc.

In block 712, the device processor may determine an aggregate intended transmit power of the one or more non-measured RATs during the upcoming time window, such as by performing operations similar to those described with reference to block 710 to determine the intended transmit powers for each of the one or more non-measured RATs and summing the respective intended transmit power to produce the aggregate intended transmit power. In some embodiments, the intended aggregate transmit power of the one or more non-measured RATs may reflect the extent to which the one or more non-measured RATs' transmissions during the upcoming time window will artificially raise the measured RAT's power measurement. In some embodiments in which there is only one non-measured RAT scheduled to transmit during the upcoming time window, the aggregate intended transmit power may be the intended transmit power of that non-measured RAT. In some embodiments, the device processor may determine the aggregate intended transmit power for only the one or more non-measured RATs that are not scheduled to implement Tx blanking during the upcoming window in order to better approximate the actual aggregate transmit power of the one or more non-measured RATs that may be expected during the upcoming time window. In other words, a non-measured RAT performing Tx blanking may not impact the measured RAT's power measurement.

In determination block 714, the device processor may determine whether transmissions of the one or more non-measured RATs will adversely affect a power measurement of the measured RAT (e.g., as measured by a power detector) during the upcoming time window based on the aggregate intended transmit power of the one or more non-measured RATs as determined in block 712 and the intended transmit power of the measured RAT as determined in block 710.

In some embodiments of the operations performed in determination block 714, the device processor may determine whether the aggregate intended transmit power of the one or more non-measured RATs is less than or equal to a transmit power level threshold value (referred to as a “transmit threshold”), which may be a value set based on the intended transmit power of the measured RAT. In such embodiments, when the intended transmit power of the one or more non-measured RATs is less than or equal to the transmit threshold, the transmissions of the one or more non-measured RATs may not adversely affect a power detector's measurement of the measured RAT's transmit power during the upcoming time window or may only affect the power detector's measurement by a small or acceptable amount, thereby maintaining the integrity and relative accuracy of that power measurement. However, in the event that the aggregate intended transmit power of the one or more non-measured RATs exceeds the transmit threshold, the transmissions of the one or more non-measured RATs may noticeably contribute to or skew the power measurement of the measured RAT's transmit power, such as by a non-trivial or an unacceptable amount.

Thus, in response to determining that the transmissions of the one or more non-measured RATs during the upcoming time window will adversely affect a power measurement of the measured RAT's transmit power based on the intended transmit power of the measured RAT and the aggregate intended transmit power of the one or more non-measured RATs (i.e., determination block 714=“Yes”), the device processor may determine that the upcoming time window is unsuitable for taking an RF output power measurement of the measured RAT in block 718, at which point the processor may optionally determine whether a threshold number of total attempts to identify a suitable upcoming window has been reached in optional determination block 610 of the method 600.

In response to determining that the one or more non-measured RATs are not scheduled to transmit during the upcoming time window (i.e., determination block 708=“No”) or in response to determining that the transmissions of the one or more non-measured RATs will not adversely affect a power measurement of the measured RAT's transmit power during the upcoming time window (i.e., determination block 714=“No”), the device processor may determine that the upcoming time window is suitable for the power detector to take an accurate RF output power measurement of the measured RAT, in block 716, and the device processor may proceed to configure/schedule the power detector to take an RF output power measurement of the measured RAT during the upcoming time window in block 612 of the method 600. In other words, the device processor may determine that the power detector will be able to take an accurate RF output power measurement of the measured RAT during the upcoming time window because, during that window, the measured RAT is not scheduled to perform Tx blanking and at least one of the one or more non-measured RATs are not scheduled to transmit and the transmissions of the one or more non-measured RATs will not adversely affect a power measurement of the measured RAT.

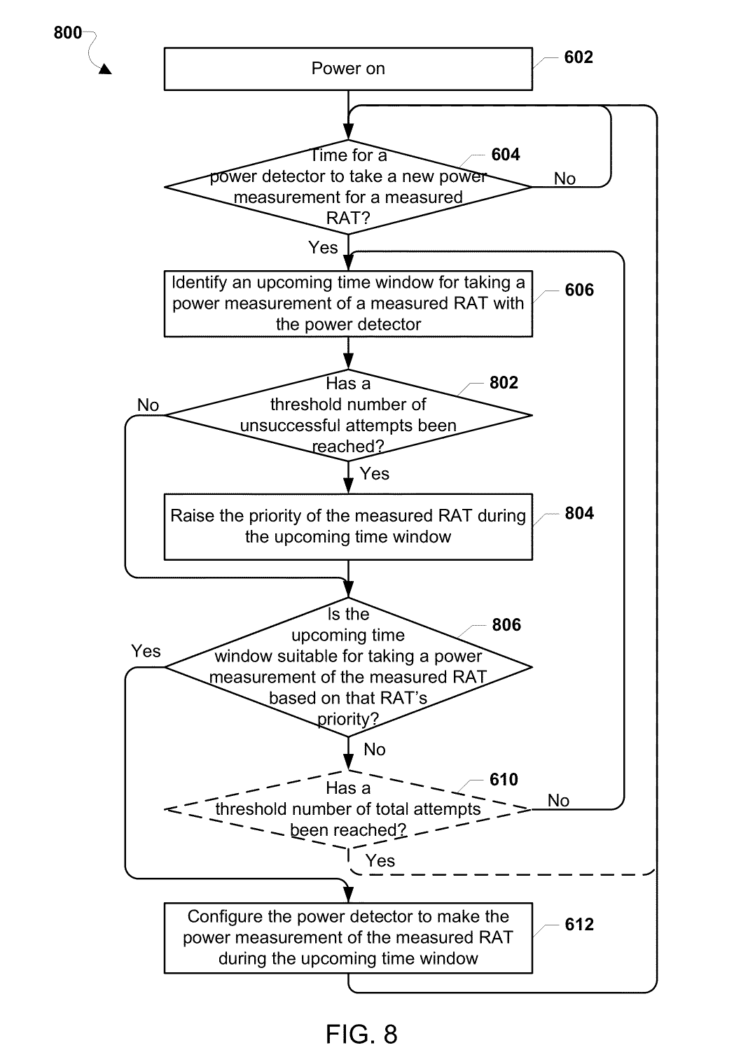

FIG. 8 illustrates a method 800 that may be implemented by a device processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) for configuring a power detector to take an RF output power measurement of a measured RAT during an upcoming time window based on the measured RAT's priority. With reference to FIGS. 1-8, the operations of method 800 implement some embodiments of the operations of the method 600 (e.g., described with reference to FIG. 6).

The priority of a measured RAT relative to the priorities of one or more non-measured RATs operating on the same mobile communication device may affect the ability of the measured RAT to transmit freely and/or prevent the measured RAT from affecting the transmitter activities of the one or more non-measured RATs. For example, a victim RAT with a higher priority than the measured RAT may cause the measured RAT to perform Tx blanking (e.g., as described with reference to FIG. 5). In another example, a measured RAT with a low priority may be unable to adjust (e.g., stop) the transmitter activities of one or more higher-priority RATs. In each of these examples, the measured RAT's low priority relative to one or more non-measured RATs may drastically reduce the number of suitable upcoming time windows in which a power detector may take an accurate RF output power measurement of the measured RAT.

To increase the likelihood that an upcoming time window will be suitable for taking accurate RF output power measurements of the measured RAT, the device processor may perform the operations of the method 800 to selectively increase the measured RAT's priority. In performing the operations of the method 800, the device processor may perform operations in blocks 604 and 606 as described with reference to the method 600. Thus, the device processor may determine whether it is time for the power detector to take a new RF output power measurement of the measured RAT in determination block 604. The device processor may also identify an upcoming time window for taking an RF output power measurement of the measured RAT in block 606 in response to determining that it is time for the power detector to take a new RF output power measurement of the measured RAT (i.e., determination block 604=“Yes”).

In determination block 802, the device processor may determine whether a threshold number of unsuccessful attempts to identify a suitable upcoming time window has been reached. In some embodiments, the device processor may maintain a count representing the number of times the device processor has failed to identify a suitable upcoming time window, and this count may be reset/reinitialized when the device processor identifies a suitable upcoming time window. In some embodiments, the threshold number of unsuccessful attempts may differ from the number of total attempts described with reference to optional determination block 610, as the threshold number of total attempts may be used to determine whether to cease attempts to identify a suitable upcoming time window until the next time the power detector needs to take an RF output power measurement, whereas the threshold number of unsuccessful attempts to identify a suitable upcoming time window may be used to determine whether to raise the priority of the measured RAT. In some embodiments, rather than maintaining a count of unsuccessful attempts to identify a suitable upcoming time window, the processor may keep track of the time since the last RF output power measurement and compare that time to a threshold duration. For example, the processor may record the time when an RF output power measurement is obtain, and then determine the duration since the last measurement by comparing the recorded time to the present time (e.g., in a subtraction operation).

In response to determining that a threshold number of unsuccessful attempts to identify a suitable upcoming time window has been reached (or a threshold time since the last measurement has elapsed) (i.e., determination block 802=“Yes”), the device processor may raise the priority of the measured RAT during the upcoming time window, in block 804. As described, by raising the priority of the measured RAT during the upcoming time window, the device processor may increase the likelihood that the measured RAT may not perform Tx blanking or reduce its transmit power during the upcoming time window, and/or the likelihood that one or more non-measured RATs may be configured to perform Tx blanking during the upcoming time window. In some embodiments, raising the measured RAT's priority may also (or alternatively) increase the likelihood that the one or more non-measured RATs will be configured to reduce their transmit power during the upcoming time window to a level that will not prevent the power detector from taking an accurate power measurement for the measured RAT.

In some embodiments of the operations performed in block 804, the device processor may raise the measured RAT's priority incrementally (e.g., from a “low” priority to a “medium” priority). In such some embodiments, the threshold number of unsuccessful attempts (or threshold time since the last measurement) may include multiple threshold values corresponding to increasing priority levels. For example, after five unsuccessful attempts, the device processor may raise the measured RAT's priority from “low” to “medium-low,” and after ten unsuccessful attempts, the processor may raise the measured RAT's priority from “medium-low” to “medium” or “high.” In some embodiments, the device processor may initially raise the measured RAT's priority to the highest possible priority, thereby ensuring that the upcoming time window will be suitable for the power detector to take an accurate RF output power measurement of the measured RAT. In some embodiments, the device processor may configure the measured RAT to have an increased priority only during the upcoming time window (i.e., the measured RAT may have a raised priority during the upcoming time window and may revert to a “normal” or “default” priority when the upcoming time window ends).

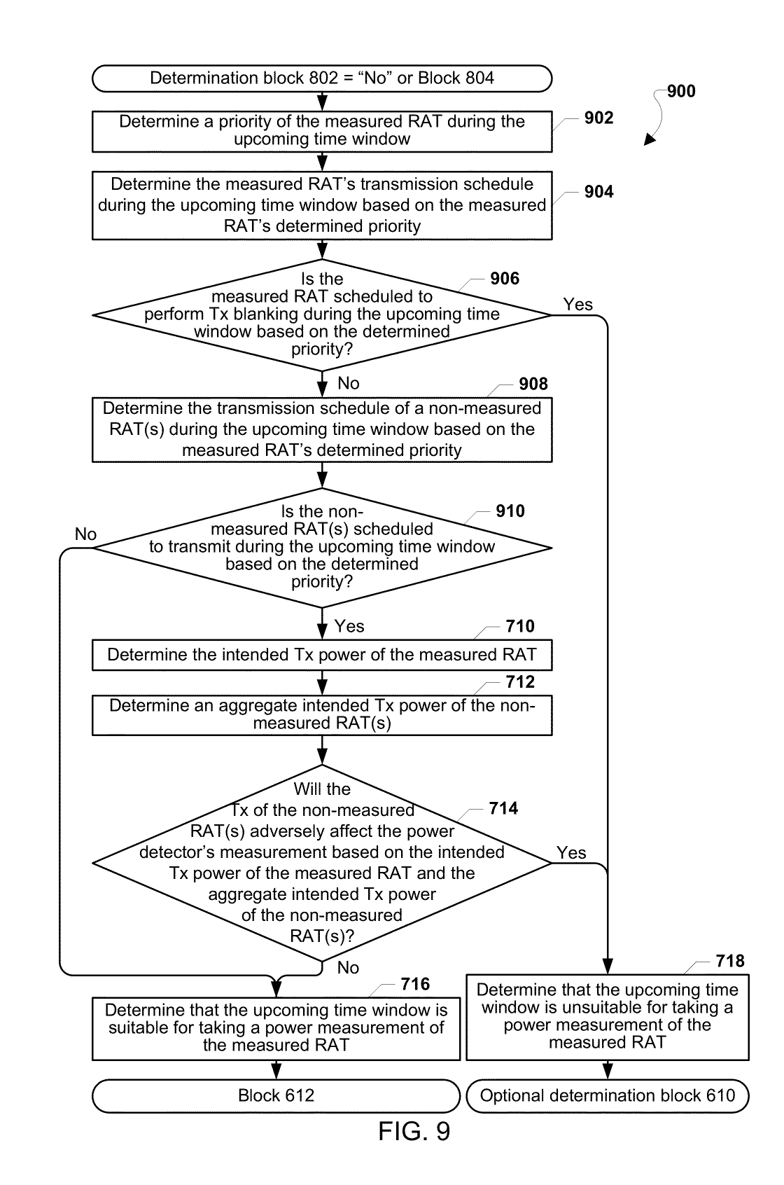

In response to determining that a threshold number of unsuccessful attempts has not been reached (or a threshold time since the last measurement has not yet elapsed) (i.e., determination block 802=“No”) or in response to raising the priority of the measured RAT during the upcoming time window in block 804, the device processor may determine whether the upcoming time window is suitable for taking an RF output power measurement of the measured RAT based on the measured RAT's priority, in determination block 806 (e.g., as described with reference to FIG. 9). In other words, the device processor may determine whether, based on the measured RAT's priority, the measured RAT will not be performing Tx blanking and the one or more non-measured RATs will not be transmitting or will be transmitting at reduced transmit power (i.e., to minimize interference with the measured RAT's power measurements) during the upcoming time window.

In response to determining that the upcoming time window is not suitable for taking an RF output power measurement of the measured RAT based on the measured RAT's priority (i.e., determination block 806=“No”), the device processor may optionally determine whether a threshold number of total attempts has been reached in optional determination block 610 as described with reference to the method 600. In response to determining that the threshold number of total attempts has not been reached (i.e., optional determination block 610=“No”), the device processor may repeat the operations of block 606 by identifying another upcoming time window for taking an RF output power measurement of the measured RAT and may continue to execute the operations of the method 800 as described. In response to determining that the threshold number of total attempts has been reached (i.e., optional determination block 610=“Yes”), the processor may again determine whether it is time for the power detector to take a new RF output power measurement of the measured RAT, in determination block 604, and may continue to execute the operations of the method 800 as described.

In response to determining that the upcoming time window is suitable for taking an RF output power measurement of the measured RAT based on the measured RAT's priority (i.e., determination block 806=“Yes”), the device processor may configure/schedule the power detector to take the RF output power measurement of the measured RAT during the upcoming time window, in block 612, and may continue to execute the operations of the method 800 as described. In some embodiments (not shown), the device processor may also reset/reinitialize the count of the number of unsuccessful attempts to identify a suitable upcoming time window in response to determining that the upcoming time window is suitable.

FIG. 9 illustrates a method 900 that may be implemented by a device processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) for determining whether an upcoming time window is suitable for taking an RF output power measure of a measured RAT based on the measured RAT's priority. The operations of the method 900 implement some embodiments of the operations of determination block 806 of the method 800 described with reference to FIG. 8. Thus, with reference to FIGS. 1-9, the device processor may begin performing the operations of the method 900 in response to raising the priority of the measured RAT during an upcoming time window in block 804 of the method 800 or in response to determining that a threshold number of unsuccessful attempts to identify a suitable upcoming time window has not been reached (i.e., determination block 802=“No”).

The device processor may determine the measured RAT's priority during an upcoming time window, in block 902, such as by querying a coexistence manager or referring to a look-up table stored in memory of priority values assigned to the RATs operating on the mobile communication device for the upcoming time window. For example, the device processor may determine that the measured RAT will have a “low” priority during the upcoming time window.

In block 904, the device processor may also determine the measured RAT's transmission schedule during an upcoming time window based on the measured RAT's priority determined in block 902. As described with reference to determination block 704 of the method 700, the device processor may identify one or more non-measured RATs that may be receiving transmissions during the upcoming time window and may compare those one or more non-measured RATs' priorities with the measured RAT's priority to determine whether the measured RAT will be forced to perform Tx blanking during the upcoming time window to accommodate the reception activities of higher-priority, non-measured RATs.

Thus, based on the measured RAT's priority determined in block 902, the device processor may determine whether the measured RAT is scheduled to perform Tx blanking during the upcoming time window in determination block 906. In response to determining that the measured RAT is scheduled to perform Tx blanking during an upcoming time window based on the measured RAT's determined priority (i.e., determination block 906=“Yes”), the device processor may determine that the upcoming time window is unsuitable for taking an RF output power measurement of the measured RAT in block 718, such as by performing operations similar to those described with reference to block 718 of the method 700. The device processor may determine whether a threshold number of total attempts to identify a suitable upcoming time window has been reached in optional determination block 610 and may continue to execute the operations of the method 600.

In response to determining that the measured RAT is not scheduled to perform Tx blanking during an upcoming time window based on the measured RAT's determine priority (i.e., determination block 906=“No”), in block 908, the device processor may determine the transmission schedule of one or more other RATs during an upcoming time window based on the measured RAT's priority determined in block 902. In some embodiments, the device processor may determine whether the priority of the measured RAT will prevent one or more non-measured RATs from transmitting during the upcoming time window. In other words, the device processor may determine whether the measured RAT's higher priority will result in the low-priority, non-measured RATs' having to perform Tx blanking or reduce their transmit powers, thus enabling the RF output power detector to take an accurate reading of the measured RAT.

In determination block 910, the device processor may determine whether one or more non-measured RATs are scheduled to transmit during the upcoming time window based on the measured RAT's priority determined in block 902, such as by determining whether the one or more non-measured RATs will be configured to perform Tx blanking in light of the measured RAT's priority. In some embodiments, the device processor may determine whether every non-measured RAT is schedule not to transmit during the upcoming time window because transmissions from even one non-measured RAT may corrupt the power detector's measurements of the measured RAT.

In response to determining that the one or more non-measured RATs are scheduled to transmit during an upcoming time window based on the measured RAT's determined priority (i.e., determination block 910=“Yes”), the device processor may determine the intended transmit power of the measured RAT in block 710 and may determine an aggregate intended transmit power of the one or more non-measured RATs in block 712. In determination block 714, the device processor may determine whether the transmissions of the one or more non-measured RATs during the upcoming time window will adversely affect a power measurement of the measured RAT's transmit power based on the intended transmit power of the measured RAT as determined in block 710 and the aggregate intended transmit power of the one or more non-measured RATs as determined in block 712. In performing the operations of blocks 710-714, the device processor may perform operations substantially similar to those operations performed in block 710-714 of the method 700. Thus, in response to determining that the transmissions of the one or more non-measured RATs will adversely affect a power measurement of the measured RAT's transmit power during the upcoming time window (i.e., determination block 714=“Yes”), the device processor may determine that the upcoming time window is unsuitable for the power detector to take an RF output power measurement of the measured RAT in block 718 as described with reference to the method 700. The device processor may determine whether a total number of attempts to identify a suitable upcoming time window has been reached in optional determination block 610 and may continue to execute the operations of the method 600 (e.g., as described with reference to FIG. 6).

In response to determining that the one or more non-measured RATs are not scheduled to transmit during an upcoming time window based on the measured RAT's determine priority (i.e., determination block 910=“No”) or in response to determining that the transmissions of the one or more non-measured RATs will not adversely affect a power measurement of the measured RAT's transmit power during the upcoming time window (i.e., determination block 714=“No”), the device processor may determine that the upcoming time window is suitable for taking an accurate RF output power measure of the measured RAT in block 716 (e.g., as described with reference to FIG. 7). The device processor may configure/schedule the power detector to take an RF output power measurement of the measured RAT during the upcoming time window process in block 612 and continue to execute the operations of the method 600 (e.g., as described with reference to FIG. 6).

FIG. 10 illustrates a method 1000 that may be implemented by a device processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) for configuring/scheduling a power detector to take an RF output power measurement of a measured RAT during an upcoming time window based on the measured RAT's priority and the composite transmission profile for one or more non-measured RATs during the upcoming time window.

In some situations, such as when the measured RAT has a good link quality and thus a low Tx power but the non-measured RAT has poor link quality and thus is using a high Tx power, increasing the priority of the measured RAT may result in a radio link control protocol initiating a handover of the non-measured RAT to another cell that exhibits better link quality (i.e., a stronger signal). As a result of such a handover, the non-measured RAT may begin transmitting at lower power. If the new transmit power of the non-measured RAT after the handover is low enough, it may no longer interfere with power measurements of the measured RAT. In other words, of the need to backing off the transmit power of the non-measured RAT or implement Tx blanking may be obviated by the non-measured RAT handing over to a stronger cell as a result of increasing the priority of the measured RAT.

As described (e.g., with reference to FIG. 8), the priority of a measured RAT may be increased in order to increase the likelihood that an upcoming window will be suitable for a power detector to take an accurate RF output power measurement of the measured RAT. In further embodiments, the device processor may analyze the composite transmission profile (i.e., the combined transmission activities) of the non-measured RATs for an upcoming time window to quickly determine whether to automatically raise the measured RAT's priority during the upcoming time window as described below.

The operations of method 1000 implement some embodiments of the operations of method 800 described with reference to FIG. 8. Thus, with reference to FIGS. 1-10, the device processor may begin performing the operations of the method 1000 by performing the operations of blocks 604 and 606 as described with reference to the methods 600, 800. In other words, the device processor may determine whether it is time for a power detector to take a new RF output power measurement in determination block 604 and may identify an upcoming time window for taking an RF output power measurement with the measured RAT in block 606 in response to determining that it is time to take a new RF output power measurement (i.e., determination block 604=“Yes”).

In block 1002, the device processor may determine the composite transmission profile for one or more other RATs during the upcoming time window. In some embodiments, the composite transmission profile may be a characterization of the transmission activities of the one or more non-measured RATs during the upcoming time window. For example, the composite transmission profile may indicate that the one or more non-measured RATs will be transmitting for a substantial amount of the upcoming time window (or the entire time) (i.e., the composite transmission profile has a “high duty cycle”). The composite transmission profile may alternatively indicate that the non-measured RAT will not be transmitting for a substantial amount of the upcoming time window (i.e., the composite transmission profile has a “low duty cycle”).

The device processor may determine whether the composite transmission profile determined in block 1002 has a low duty cycle in determination block 1004. As described, a high duty cycle may indicate a significant amount of transmitter activity during the upcoming time window, which may make it impossible for the power detector to take an accurate RF output power measurement of the measured RAT. Thus, in response to determining that the composite transmission profile does not have a low Tx duty cycle (i.e., determination block 1004=“No”), the device processor may automatically raise the priority of the measured RAT during the upcoming time window in block 804 (e.g., as described above with reference to the method 800) regardless of the number of previously unsuccessful attempts to identify a suitable upcoming time window that have occurred.

Alternatively, a low Tx duty cycle may indicate that there is low or no transmitter activity during the upcoming time window or that the one or more non-measured RATs' transmissions are time-based and predictable, thereby indicating a higher likelihood that the upcoming time window will be suitable for taking an accurate RF output power measurement of the measured RAT without automatically raising the measured RAT's priority during the upcoming time window. Thus, in response to determining that the composite transmission profile has a low transmission duty cycle (i.e., determination block 1004=“Yes”), the device processor may determine whether a threshold number of unsuccessful attempts has been reached in determination block 802 as described with reference to the method 800. In order words, while the device processor may not automatically raise the priority of the measured RAT in response to determining that the composite transmission profile has a low duty cycle during the upcoming time window, the processor may still raise the measured RAT's priority in response to failing to identify a suitable upcoming time window the threshold number of times. Thus, in response to determining that a threshold number of unsuccessful attempts has been reached (i.e., determination block 802=“Yes”), the device processor may raise the priority of the measured RAT during the upcoming time window in block 804 as described.

In response to determining that a threshold number of unsuccessful attempts has not been reached (i.e., determination block 802=“No”) or in response to raising the priority of the measured RAT in block 804, the device processor may determine whether the upcoming time window is suitable for taking an RF output power measurement of the measured RAT based on the measured RAT's priority, in determination block 806 (e.g., as described with reference to the method 800).

In response to determining that the upcoming time window is not suitable for taking RF output power measurement with the measured RAT based on the measured RAT's priority (i.e., determination block 806=“No”), the device processor may optionally determine whether a threshold number of total attempts has been reached in optional determination block 610 as described with reference to the method 600. In response to determining that threshold number of total attempts has been reached (i.e., optional determination block 610=“Yes”), the device processor may repeat the above operations in a loop in determination block 604 by determining whether it is time for the power detector to take a new RF output power measurement. In some embodiments (not shown), the device processor may also reset/reinitialize the number of total attempts to identify a suitable upcoming time window (e.g., as described with reference to FIG. 8).

In response to determining that a threshold number of total attempts to identify a suitable upcoming time window has not been reached (i.e., optional determination block 610=“No”), the device processor may repeat the above operations in a loop in block 606 by identifying an upcoming time window for taking an RF output power measurement with the measured RAT.

In response to determining that the upcoming time window is suitable for taking an RF output power measurement of the measured RAT based on the measured RAT's priority (i.e., determination block 806=“Yes”), the device processor may configure/schedule the measured RAT to take the RF output power measurement during the upcoming time window in block 612 (e.g., as described with reference to FIG. 6). The device processor may also reset/reinitialize the number of unsuccessful attempts to identify a suitable upcoming time window as described above. The device processor may repeat the operations in a continuous loop such as by determining again whether it is time for the power detector to take a new RF output power measurement of the measured RAT, in determination block 604.

FIG. 11 illustrates a method 1100 that may be implemented by a device processor (e.g., the general purpose processor 206 of FIG. 2, the baseband modem processor 216, the coexistence management unit 230, a separate controller, and/or the like) on a mobile communication device (e.g., the mobile communication device 200 of FIG. 2) for determining whether an upcoming time window is suitable for taking an RF output power measurement of a measured RAT when the composite transmission profile of one or more other RATs during the upcoming time window has a low transmission duty cycle.

As described (e.g., with reference to FIG. 10), a composite transmission profile during an upcoming time window may indicate low or no transmitter activity from one or more non-measured RATs or that the one or more non-measured RATs' transmissions are time-based and predictable (e.g., TDD). For example, the composite transmission profile for one or more non-measured RATs during an upcoming time window may have a low duty cycle when the one or more non-measured RATs transmit for only one out of eight frames and do not transmit for the remaining seven out of eight frames. In such a situation, the device processor may perform the operations of the method 1100 to determine whether there is a gap in the non-measured RAT(s)' transmission during which the power detector may take an accurate RF output power measurement of the measured RAT.

The operations of the method 1100 implement some embodiments of the operations performed in blocks 806 and 612 of the method 1000 described with reference to FIG. 10. Thus, with reference to FIGS. 1-11, the device processor may begin performing the operations of the method 1100 in response to determining that the composite transmission profile has a low duty cycle (i.e., determination block 1004=“Yes”) and one of raising the priority of the measured RAT during an upcoming time window in block 804 of the method 1000 and determining that a threshold number of unsuccessful attempts has not been reached in determination block 802 of the method 1000.

As described (e.g., with reference to FIG. 7), the processor device may determine the measured RAT's transmission schedule during the upcoming time window in block 702 and may determine whether the measured RAT is scheduled to perform Tx blanking during an upcoming time window in determination block 704. In response to determining that the measured RAT is scheduled to perform Tx blanking on the upcoming time window (i.e., determination block 704=“Yes”), the device processor may determine that the upcoming time window is unsuitable for taking an RF output power measurement of the measured RAT, in block 718. The device processor may determine whether a threshold number of total attempts has been reached in optional determination block 610 of the method 1000 (e.g., as described with reference to FIG. 10).

In response to determining that the measured RAT is not scheduled to perform Tx blanking during the upcoming time window (i.e., determination block 704=“No”), the processor may determine the transmission schedule of one or more non-measured RATs that have a composite transmission profile with a low duty cycle during the upcoming time window in block 1102, such as by identifying the timing of the one or more non-measured RATs' transmissions. For example, the one or more non-measured RATs may alternate between transmitting for a certain period of time and not transmitting for another period of time.

In determination block 1104, the device processor may determine whether the power detector is able to take a measurement in a transmission gap during the upcoming time window based on the transmission schedule of the one or more other RATs. In some embodiments, the device processor may determine whether the power detector will have enough time to take an accurate RF output power measurement of the measured RAT in between the one or more non-measured RATs' transmissions. For example, the device processor may determine that the power detector needs 0.25 seconds to take a measurement and that there will be a transmission gap of 0.5 seconds during the upcoming time window. In this example, the device processor may determine that the power detector would be able to take a measurement during the 0.5 second transmission gap.

In response to determining that the power detector is not able to take a measurement during the transmission gap during an upcoming time window based on the transmission schedule of the one or more other RATs (i.e., determination block 1104=“No”), the device processor may determine that the upcoming time window is unsuitable for taking an accurate RF output power measurement of the measured RAT in block 718 as described. The device processor may determine whether a threshold number of total attempts to identify a suitable upcoming time window has been reached in optional determination block 610 of the method 1000 (e.g., as described with reference to FIG. 10) and may continue performing the operations of the method 1000.

In response to determining that the power detector is able to take an accurate measurement of the measured RAT in a transmission gap during the upcoming time window based on the transmission schedules of the one or more other RATs (i.e., determination block 1104=“Yes”), the device processor may determine that the upcoming time window is suitable for taking an RF output power measurement of the measured RAT in block 716 (e.g., as described with reference to the methods 700, 900). The device processor may also configure the power detector to take an RF output power measurement of the measured RAT during the transmission gap of the upcoming time window in block 1106, such as by scheduling the power detector to begin the RF output power measurement when the transmission gap begins. The device processor may again determine whether it is time for the power detector to take another RF output power measurement of the measured RAT in determination block 604 of the method 1000 (e.g., as described with reference to FIG. 10).

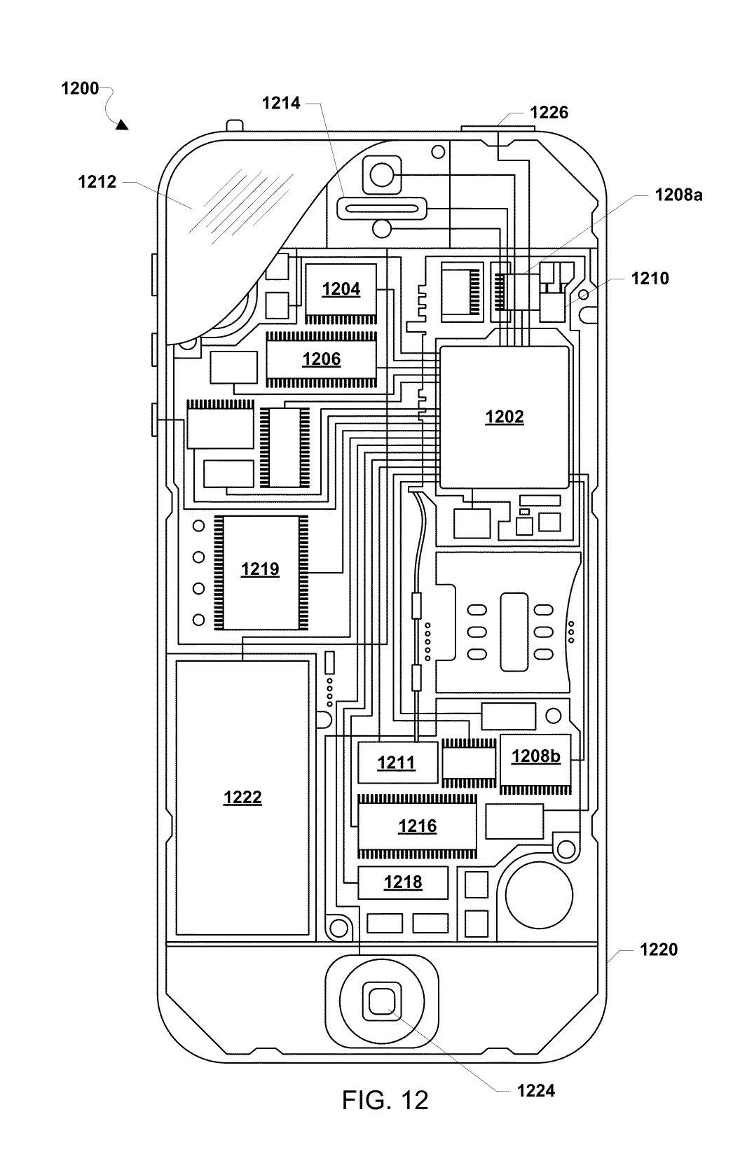

Various embodiments may be implemented in any of a variety of mobile communication devices, an example of which (e.g., a mobile communication device 1200) is illustrated in FIG. 12. According to various embodiments, the mobile communication device 1200 may be similar to the mobile communication devices 110, 120, 200 as described above with reference to FIGS. 1-3. As such, the mobile communication device 1200 may implement the methods 600, 700, 800, 900, 1000, 1100 of FIGS. 6-11.

The mobile communication device 1200 may include a processor 1202 coupled to a touchscreen controller 1204 and an internal memory 1206. The processor 1202 may be one or more multi-core integrated circuits designated for general or specific processing tasks. The internal memory 1206 may be volatile or non-volatile memory, and may also be secure and/or encrypted memory, or unsecure and/or unencrypted memory, or any combination thereof. The touchscreen controller 1204 and the processor 1202 may also be coupled to a touchscreen panel 1212, such as a resistive-sensing touchscreen, capacitive-sensing touchscreen, infrared sensing touchscreen, etc. Additionally, the display of the mobile communication device 1200 need not have touch screen capability.

The mobile communication device 1200 may have two or more radio signal transceivers 1208a, 1208b (e.g., Peanut, Bluetooth, Zigbee, Wi-Fi, RF radio) and two or more antennae 1210, 1211, for sending and receiving communications, coupled to each other and/or to the processor 1202. The transceivers 1208a, 1208b and antennae 1210, 1211 may be used with the above-mentioned circuitry to implement the various wireless transmission protocol stacks and interfaces. The mobile communication device 1200 may include one or more SIM cards (e.g., a SIM 1219) coupled to the transceivers 1208a, 1208b and/or the processor 1202 and configured as described above. The mobile communication device 1200 may include one or more cellular network wireless modem chip(s) 1216 coupled to the processor 1202 and antennae 1210, 1211 that enables communication via two or more cellular networks via two or more radio access technologies.

The mobile communication device 1200 may include a peripheral device connection interface 1218 coupled to the processor 1202. The peripheral device connection interface 1218 may be singularly configured to accept one type of connection, or may be configured to accept various types of physical and communication connections, common or proprietary, such as USB, FireWire, Thunderbolt, or PCIe. The peripheral device connection interface 1218 may also be coupled to a similarly configured peripheral device connection port (not shown).

The mobile communication device 1200 may also include speakers 1214 for providing audio outputs. The mobile communication device 1200 may also include a housing 1220, constructed of a plastic, metal, or a combination of materials, for containing all or some of the components discussed herein. The mobile communication device 1200 may include a power source 1222 coupled to the processor 1202, such as a disposable or rechargeable battery. The rechargeable battery may also be coupled to the peripheral device connection port to receive a charging current from a source external to the mobile communication device 1200. The mobile communication device 1200 may also include a physical button 1224 for receiving user inputs. The mobile communication device 1200 may also include a power button 1226 for turning the mobile communication device 1200 on and off.

The foregoing method descriptions and the process flow diagrams are provided merely as illustrative examples and are not intended to require or imply that the steps of various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The hardware used to implement the various illustrative logics, logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some steps or methods may be performed by circuitry that is specific to a given function.

In one or more exemplary aspects, the functions described may be implemented in hardware, software, firmware, or any combination thereof. If implemented in software, the functions may be stored as one or more instructions or code on a non-transitory computer-readable storage medium or non-transitory processor-readable storage medium. The steps of a method or algorithm disclosed herein may be embodied in a processor-executable software module which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A method for measuring transmitter power of a radio access technology (RAT) operating on a mobile communication device, comprising:
identifying an upcoming time window for taking a radio-frequency (RF) output power measurement of the RAT with a power detector;
determining whether the upcoming time window is suitable for taking an accurate RF output power measurement of the RAT; and
configuring the power detector to take an RF output power measurement of the RAT during the upcoming time window in response to determining that the upcoming time window is suitable for taking an accurate RF output power measurement of the RAT.

2. The method of claim 1, wherein identifying an upcoming time window for taking an RF output power measurement of the RAT comprises identifying an upcoming time window during which the RAT is scheduled to transmit at a consistent RF output power level.

3. The method of claim 1, wherein:
determining whether the upcoming time window is suitable for taking an accurate RF output power measurement of the RAT comprises:
determining a composite transmission profile for at least one other RAT during the upcoming time window;
determining whether the composite transmission profile for the at least one other RAT has a low duty cycle; and
determining whether the power detector is able to take an RF output power measurement of the RAT during a transmission gap of the at least one other RAT in the upcoming time window in response to determining that the composite transmission profile has a low duty cycle; and
configuring the power detector to take an RF output power measurement of the RAT during the upcoming time window comprises configuring the power detector to take an RF output power measurement of the RAT during the transmission gap of the at least one other RAT in the upcoming time window in response to determining that the power detector is able to take an RF output power measurement of the RAT during the transmission gap of the at least one other RAT.

4. The method of claim 1, further comprising:
determining a period of time since a last RF output power measurement of the RAT was taken; and
raising a priority of the RAT during the upcoming time window in response to determining that the period of time since the last RF output power measurement of the RAT was taken exceeds a threshold amount of time,
wherein determining whether the upcoming time window is suitable for taking an accurate RF output power measurement of the RAT comprises determining whether the upcoming time window is suitable for taking an accurate RF output power measurement for the RAT based on the priority of the RAT during the upcoming time window.

5. The method of claim 1, further comprising:
determining whether a threshold number of total attempts to take an RF output power measurement for the RAT has been reached in response to determining that the upcoming time window is not suitable for taking an accurate RF output power measurement of the RAT; and
identifying another upcoming time window for taking an RF output power measurement of the RAT in response to determining that the threshold number of total attempts to take an RF output power measurement for the RAT has not been reached.

6. The method of claim 1, wherein:
determining whether the upcoming time window is suitable for taking an accurate RF output power measurement of the RAT comprises:
determining a transmission schedule for the RAT during the upcoming time window;
determining whether the RAT is scheduled to perform transmit blanking during the upcoming time window;
determining a transmission schedule of at least one other RAT during the upcoming time window; and
determining whether the at least one other RAT is scheduled to transmit during the upcoming time window; and
configuring the power detector to take an RF output power measurement of the RAT during the upcoming time window comprises configuring the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

7. The method of claim 6, wherein:
determining whether the upcoming time window is suitable for taking an accurate RF output power measurement of the RAT further comprises determining, in response to determining that the at least one other RAT is scheduled to transmit during the upcoming time window, whether transmissions of the at least one other RAT will adversely affect an RF output power measurement of the RAT during the upcoming time window based on an aggregate intended transmit power of the at least one other RAT during the upcoming time window and an intended transmit power of the RAT during the upcoming time window; and
configuring the power detector to take an RF output power measurement of the RAT during the upcoming time window further comprises configuring the power detector to take an RF output power measurement of the RAT during the upcoming time window in response to determining that the RAT is not scheduled to perform transmit blanking during the upcoming time window and that the transmissions of the at least one other RAT will not adversely affect an RF output power measurement of the RAT during the upcoming time window.

8. The method of claim 1, further comprising:
determining whether a number of unsuccessful attempts to identify a suitable upcoming time window exceeds a threshold; and
raising a priority of the RAT during the upcoming time window in response to determining that the number of unsuccessful attempts to identify a suitable upcoming time window exceeds the threshold,
wherein determining whether the upcoming time window is suitable for taking an accurate RF output power measurement of the RAT comprises determining whether the upcoming time window is suitable for taking an accurate RF output power measurement for the RAT based on the priority of the RAT during the upcoming time window.

9. The method of claim 8, further comprising:
determining a composite transmission profile for at least one other RAT during the upcoming time window; and
determining whether the composite transmission profile for the at least one other RAT has a low duty cycle,
wherein raising a priority of the RAT during the upcoming time window comprises immediately raising the priority of the RAT during the upcoming time window in response to determining that the composite transmission profile for the at least one other RAT does not have a low duty cycle.

10. The method of claim 8, wherein:
determining whether the upcoming time window is suitable for taking an accurate RF output power measurement for the RAT based on the priority of the RAT during the upcoming time window comprises:
determining the priority of the RAT during the upcoming time window;
determining a transmission schedule of the RAT during the upcoming time window based on the determined priority of the RAT;
determining whether the RAT is scheduled to perform transmit blanking during the upcoming time window;
determining a transmission schedule of at least one other RAT during the upcoming time window based on the determined priority of the RAT; and
determining whether the at least one other RAT is scheduled to transmit during the upcoming time window; and
configuring the power detector to take an RF output power measurement of the RAT during the upcoming time window comprises configuring the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

11. The method of claim 10, wherein:
determining whether the upcoming time window is suitable for taking an accurate RF output power measurement for the RAT based on the priority of the RAT during the upcoming time window further comprises determining, in response to determining that the at least one other RAT is scheduled to transmit during the upcoming time window, whether transmissions of the at least one other RAT will adversely affect an RF output power measurement of the RAT during the upcoming time window based on an aggregate intended transmit power of the at least one other RAT during the upcoming time window and an intended transmit power of the RAT during the upcoming time window; and
configuring the power detector to take an RF output power measurement of the RAT during the upcoming time window further comprises configuring the power detector to take an RF output power measurement of the RAT during the upcoming time window in response to determining that the RAT is not scheduled to perform transmit blanking during the upcoming time window and that the transmissions of the at least one other RAT will not adversely affect an RF output power measurement of the RAT during the upcoming time window.

12. A mobile communication device, comprising:
a power detector; and
a processor coupled to the power detector, wherein the processor is configured to:
identify an upcoming time window for taking a radio-frequency (RF) output power measurement of a radio access technology (RAT) with the power detector;
determine whether the upcoming time window is suitable for taking an accurate RF output power measurement of the RAT; and
configure the power detector to take an RF output power measurement of the RAT during the upcoming time window in response to determining that the upcoming time window is suitable for taking an accurate RF output power measurement of the RAT.

13. The mobile communication device of claim 12, wherein the processor is further configured to identify an upcoming time window during which the RAT is scheduled to transmit at a consistent RF output power level.

14. The mobile communication device of claim 12, wherein the processor is further configured to:
determine a composite transmission profile for at least one other RAT during the upcoming time window;
determine whether the composite transmission profile for the at least one other RAT has a low duty cycle;
determine whether the power detector is able to take an RF output power measurement of the RAT during a transmission gap of the at least one other RAT in the upcoming time window in response to determining that the composite transmission profile has a low duty cycle; and
configure the power detector to take an RF output power measurement of the RAT during the transmission gap of the at least one other RAT in the upcoming time window in response to determining that the power detector is able to take an RF output power measurement of the RAT during the transmission gap of the at least one other RAT.

15. The mobile communication device of claim 12, wherein the processor is further configured to:
determine a period of time since a last RF output power measurement of the RAT was taken;
raise a priority of the RAT during the upcoming time window in response to determining that the period of time since the last RF output power measurement of the RAT was taken exceeds a threshold amount of time; and
determine whether the upcoming time window is suitable for taking an accurate RF output power measurement for the RAT based on the priority of the RAT during the upcoming time window.

16. The mobile communication device of claim 12, wherein the processor is further configured to:
determine whether a threshold number of total attempts to take an RF output power measurement for the RAT has been reached in response to determining that the upcoming time window is not suitable for taking an accurate RF output power measurement of the RAT; and
identify another upcoming time window for taking an RF output power measurement of the RAT in response to determining that the threshold number of total attempts to take an RF output power measurement for the RAT has not been reached.

17. The mobile communication device of claim 12, wherein the processor is further configured to:
determine a transmission schedule for the RAT during the upcoming time window;
determine whether the RAT is scheduled to perform transmit blanking during the upcoming time window;
determine a transmission schedule of at least one other RAT during the upcoming time window;
determine whether the at least one other RAT is scheduled to transmit during the upcoming time window; and
configure the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

18. The mobile communication device of claim 17, wherein the processor is further configured to:
determine, in response to determining that the at least one other RAT is scheduled to transmit during the upcoming time window, whether transmissions of the at least one other RAT will adversely affect an RF output power measurement of the RAT during the upcoming time window based on an aggregate intended transmit power of the at least one other RAT during the upcoming time window and an intended transmit power of the RAT during the upcoming time window; and
configure the power detector to take an RF output power measurement of the RAT during the upcoming time window in response to determining that the RAT is not scheduled to perform transmit blanking during the upcoming time window and that the transmissions of the at least one other RAT will not adversely affect an RF output power measurement of the RAT during the upcoming time window.

19. The mobile communication device of claim 12, wherein the processor is further configured to:
determine whether a number of unsuccessful attempts to identify a suitable upcoming time window exceeds a threshold;
raise a priority of the RAT during the upcoming time window in response to determining that the number of unsuccessful attempts to identify a suitable upcoming time window exceeds the threshold; and
determine whether the upcoming time window is suitable for taking an accurate RF output power measurement for the RAT based on the priority of the RAT during the upcoming time window.

20. The mobile communication device of claim 19, wherein the processor is further configured to:
determine a composite transmission profile for at least one other RAT during the upcoming time window;
determine whether the composite transmission profile for the at least one other RAT has a low duty cycle; and
raise the priority of the RAT immediately during the upcoming time window in response to determining that the composite transmission profile for the at least one other RAT does not have a low duty cycle.

21. The mobile communication device of claim 19, wherein the processor is further configured to:
determine the priority of the RAT during the upcoming time window;
determine a transmission schedule of the RAT during the upcoming time window based on the determined priority of the RAT;
determine whether the RAT is scheduled to perform transmit blanking during the upcoming time window;
determine a transmission schedule of at least one other RAT during the upcoming time window based on the determined priority of the RAT;
determine whether the at least one other RAT is scheduled to transmit during the upcoming time window; and
configure the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

22. The mobile communication device of claim 21, wherein the processor is further configured to:
determine, in response to determining that the at least one other RAT is scheduled to transmit during the upcoming time window, whether transmissions of the at least one other RAT will adversely affect an RF output power measurement of the RAT during the upcoming time window based on an aggregate intended transmit power of the at least one other RAT during the upcoming time window and an intended transmit power of the RAT during the upcoming time window; and
configure the power detector to take an RF output power measurement of the RAT during the upcoming time window in response to determining that the RAT is not scheduled to perform transmit blanking during the upcoming time window and that the transmissions of the at least one other RAT will not adversely affect an RF output power measurement of the RAT during the upcoming time window.

23. A non-transitory processor-readable storage medium having stored thereon processor-executable instructions configured to cause a processor of a mobile communication device to perform operations comprising:
identifying an upcoming time window for taking a radio-frequency (RF) output power measurement of a radio access technology (RAT) with a power detector;
determining whether the upcoming time window is suitable for taking an accurate RF output power measurement of the RAT; and
configuring the power detector to take an RF output power measurement of the RAT during the upcoming time window in response to determining that the upcoming time window is suitable for taking an accurate RF output power measurement of the RAT.

24. The non-transitory processor-readable storage medium of claim 23, wherein the stored processor-executable instructions are configured to cause the mobile communication device processor to perform operations for identifying an upcoming time window for taking an RF output power measurement of the RAT, the operations comprising identifying an upcoming time window during which the RAT is scheduled to transmit at a consistent RF output power level.

25. The non-transitory processor-readable storage medium of claim 23, wherein:
the stored processor-executable instructions are configured to cause the mobile communication device processor to perform operations for determining whether the upcoming time window is suitable for taking an accurate RF output power measurement of the RAT, the operations comprising:
determining a composite transmission profile for at least one other RAT during the upcoming time window;
determining whether the composite transmission profile for the at least one other RAT has a low duty cycle; and
determining whether the power detector is able to take an RF output power measurement of the RAT during a transmission gap of the at least one other RAT in the upcoming time window in response to determining that the composite transmission profile has a low duty cycle; and
the stored processor-executable instructions are configured to cause the mobile communication device processor to perform operations for configuring the power detector to take an RF output power measurement of the RAT during the upcoming time window, the operations comprising configuring the power detector to take an RF output power measurement of the RAT during the transmission gap of the at least one other RAT in the upcoming time window in response to determining that the power detector is able to take an RF output power measurement of the RAT during the transmission gap of the at least one other RAT.

26. The non-transitory processor-readable storage medium of claim 23, wherein:
the stored processor-executable instructions are configured to cause the mobile communication device processor to perform operations further comprising:
determining a period of time since a last RF output power measurement of the RAT was taken; and
raising a priority of the RAT during the upcoming time window in response to determining that the period of time since the last RF output power measurement of the RAT was taken exceeds a threshold amount of time; and
the stored processor-executable instructions are configured to cause the mobile communication device processor to perform operations for determining whether the upcoming time window is suitable for taking an accurate RF output power measurement of the RAT, the operations comprising determining whether the upcoming time window is suitable for taking an accurate RF output power measurement for the RAT based on the priority of the RAT during the upcoming time window.

27. The non-transitory processor-readable storage medium of claim 23, wherein the stored processor-executable instructions are configured to cause the mobile communication device processor to perform operations further comprising:
determining whether a threshold number of total attempts to take an RF output power measurement for the RAT has been reached in response to determining that the upcoming time window is not suitable for taking an accurate RF output power measurement of the RAT; and
identifying another upcoming time window for taking an RF output power measurement of the RAT in response to determining that the threshold number of total attempts to take an RF output power measurement for the RAT has not been reached.

28. The non-transitory processor-readable storage medium of claim 23, wherein:
the stored processor-executable instructions are configured to cause the mobile communication device processor to perform operations for determining whether the upcoming time window is suitable for taking an accurate RF output power measurement of the RAT, the operations comprising:
determining a transmission schedule for the RAT during the upcoming time window;
determining whether the RAT is scheduled to perform transmit blanking during the upcoming time window;
determining a transmission schedule of at least one other RAT during the upcoming time window; and
determining whether the at least one other RAT is scheduled to transmit during the upcoming time window; and
the stored processor-executable instructions are configured to cause the mobile communication device processor to perform operations for configuring the power detector to take an RF output power measurement of the RAT during the upcoming time window, the operations comprising configuring the power detector to take an RF output power measurement of the RAT during the upcoming time window in response to determining that the RAT is not scheduled to perform transmit blanking during the upcoming time window and that the at least one other RAT is not scheduled to transmit during the upcoming time window.

29. The non-transitory processor-readable storage medium of claim 23, wherein:
the stored processor-executable instructions are configured to cause the mobile communication device processor to perform operations further comprising:
determining whether a number of unsuccessful attempts to identify a suitable upcoming time window exceeds a threshold; and
raising a priority of the RAT during the upcoming time window in response to determining that the number of unsuccessful attempts to identify a suitable upcoming time window exceeds the threshold; and
the stored processor-executable instructions are configured to cause the mobile communication device processor to perform operations for determining whether the upcoming time window is suitable for taking an accurate RF output power measurement of the RAT, the operations comprising determining whether the upcoming time window is suitable for taking an accurate RF output power measurement for the RAT based on the priority of the RAT during the upcoming time window.

30. A mobile communication device, comprising:
means for identifying an upcoming time window for taking a radio-frequency (RF) output power measurement of a radio access technology (RAT) with a power detector;
means for determining whether the upcoming time window is suitable for taking an accurate RF output power measurement of the RAT; and
means for configuring the power detector to take an RF output power measurement of the RAT during the upcoming time window in response to determining that the upcoming time window is suitable for taking an accurate RF output power measurement of the RAT.
